(19) United States
(12) Patent Application Publication
(10) Pub. No.: US 2025/0130265 A1
(43) Pub. Date: Apr. 24, 2025

(54) SMART POWER MONITORING SYSTEM

(71) Applicant: Circuitiq Inc., Sudbury (CA)

(72) Inventors: Luke Gordon Begley, Sudbury (CA); Jacob Andrew Cobb, Sudbury (CA); Travis Michael Hunter Dunn, Kitchener (CA)

(21) Appl. No.: 18/492,171

(22) Filed: Oct. 23, 2023

(51) Int. Cl. G01R 31/08

(52) U.S. Cl. CPC G01R 31/085; G01R 31/088

(57) ABSTRACT

A system includes a first device connected to a power line and a second device connected to a circuit breaker switch upstream of the first device. A transmitter of the first device communicates a signal pertaining to amplitude, phase, frequency, switching frequency and duty cycle of current, including multiple current signatures that include an unique first current signature from the first device and at least one second current signature associated with one or more load fixtures on the power line, with a receiver of the second device. A processor in communication with the receiver processes the signal using Fast Fourier Transform (FFT) to obtain the unique first current signature and the at least one second current signature, perform line and load mapping, and generate user intelligible data representation of the confirmation and determination.

### TECHNICAL FIELD

The present disclosure relates generally to a system and method for power monitoring. More particularly, the present disclosure relates to a smart monitoring system that may be configured to self-calibrate for monitoring the power of electrically connected networks in a pre-existing, or aging, building by tracing power lines through power load modulation and machine learning powerline detection.

### BACKGROUND

Many real estate properties across the world consist of pre-existing, or aging, buildings. These buildings may be built for residential, industrial, or commercial use. In some cases, these buildings may be more than five, ten, or even twenty years old. Such buildings may have outdated wiring systems that may not be capable of supporting electrical loads of modern appliances and other electronic devices. This often leads to overloaded circuits, which are a major fire hazard. Additionally, some wiring materials present in such buildings may degrade over time, thereby becoming outdated and presenting additional risks such as compromised safety to life and property.

Another issue with pre-existing buildings is that they were not designed for the number of electrical appliances and devices commonly used today. Use of a large number of appliances and devices can result in the overuse of extension cords and power strips that are meant for temporary use and not as a permanent solution as they tend to increase demand for electrical power on the circuit hardware including, but not limited to, wiring, switches, circuit breakers or other circuit associated hardware. To compound the issue of overloading, some of these pre-existing, or aging buildings continue to have outdated hardware such as fuse boxes, knob-and-tube wiring, or aluminum wiring that are considered unsafe by modern electrical standards.

In some cases, older electrical systems may also lack proper grounding, a safety feature in modern systems designed to help prevent electrical shocks. In other cases, older electrical systems may be less energy-efficient than modern systems as they may lack features such as energy-efficient lighting and appliances, smart thermostats or other devices operating on energy-saving technologies. Merely adding one or more current sensors or current transformers (CTs) to the circuit may not yield reliable data pertinent to the load on the circuit. If comprehensive knowledge of what else is on the circuit is not available from poor or outdated documentation of system components and performances, data input to a power monitoring system associated with such CTs becomes questionable. This could lead to inaccurate outputs and therefore, cast a doubt on the accuracy, or correctness, of the data collected by such monitoring systems.

Given these challenges, managing, servicing, and maintaining pre-existing, or aging electrical systems often requires specialized knowledge besides being, both, time and cost intensive. Further, poorly managed technical documentation and records of electrical systems installed in such properties may leave electrical personnel performing guesswork. As a consequence, updates to electrical systems become a common part of renovations in such circumstances e.g., when pre-existing, or aging properties are bought or sold. Despite these challenges, it would be helpful to ensure that pre-existing, or aging electrical systems are safe and functional, as outdated systems can present significant safety hazards.

In the recent past, tracing and identifying one plug at a time in individual circuits of a pre-existing or aging, building using a circuit tracer has been known. However, this process can be time-consuming as an operator would need to physically plug a transmitter of the circuit tracer into each outlet or connect it to each switch or fixture present on the circuit and use a receiver to trace the signal back to a breaker box where a circuit breaker associated with the corresponding outlet may be present. This process becomes laborious when dealing with large buildings especially commercial or institutional buildings in which electrification work has been carried out using circuits rendered with numerous panels, sub-panels, breakers, switches, outlets, wiring and other fixtures of increased complexity.

Additionally, one limiting factor to tracing circuits in larger buildings using conventional designs of circuit tracers is that these circuit tracers do not have the capability to discern between a wire and other obstacles, for example, a metal conduit as such obstacles weaken the tracer signal, or generate noise to an otherwise normally expected healthy signal. This poses additional challenges to detecting and determining the exact locations of circuitry elements. Further, as safety protocols need to be followed, operators of circuit tracers are required always to turn OFF electricity when connecting the transmitter to a circuit and such disconnections of electricity may be inconvenient to building occupants. Furthermore, even upon identifying a circuit, the operator of a circuit tracer will need to verify that the circuit is indeed traced correctly manually. This manual verification process might involve flipping one or more breakers to see if they turn off the correct outlet, switch, or fixture.

Additionally, some facilities may contain critical power systems i.e., power systems whose power feeds cannot be disturbed because of critical loads such as life support equipment in hospitals, and critical key infrastructure in data centers. In such cases, these power systems may require electrical workers working live during maintenance, due to the inability to confirm lines when the lines are not powered. Such scenarios present risks to the safety of the worker. Moreover, manually stored documentation, or information that is not digitally captured or stored, would remain susceptible to having information outdated, lost, or unorganized and possibly misunderstood in an emergency.

With greater strides in energy efficiency and smarter power management, smart panels are becoming increasingly prevalent in retrofit projects for older properties. Some of these panels may provide features such as real-time energy usage monitoring, wireless remote control, and circuit protection that may help in developing an efficient power management strategy. However, calibration of these smart panels within the existing systems often presents challenges during practical implementation. Moreover, simply installing a smart panel does not automatically upgrade an entire outdated electrical system to ‘smart’ status. The intelligence and efficiency of any system are only as good as the data and context it can access and comprehend.

In essence, the ability of any power monitoring system to function effectively and contribute to safety is heavily reliant on understanding the specific loads present on the lines. An undetected or unknown load can produce a distorted view of the system's overall efficiency. For instance, if a line is thought only to be supplying a known load, such as a heating, ventilation, and air condition (HVAC) system, but unknown to the operators, it may also be powering one or more undetected additional lighting circuits, and any efficiency calculations or optimization efforts for the HVAC system could be significantly skewed by the additional load from the undetected lighting circuits.

The process of power cycling (also called a restart, an on-off test, soft reboot, random reboot, automatic reboot, quick boot, and by other terms known to one skilled in the art) networks of electrical circuits to identify and isolate individual loads can be a tedious task, and often require meticulous attention to detail. In large properties with complex electrical systems, there could be a vast number of circuits to track and trace, each potentially influencing the power draw and overall efficiency of the system. The breaker cycling process required for this identification can induce power loss events, which must be accurately detected and logged to prevent false readings or overlooked equipment. Multiple power mapping devices may be needed to do this effectively and minimize disruption, which can incur additional time and costs to set up before use.

Downstream, another challenge is that upon load identification, each load must be accurately calibrated and optimally integrated with the control and monitoring systems of the smart panels. This intricate process often requires skilled professionals and advanced tools, particularly when dealing with complex electrical systems and networks of commercial or institutional buildings.

While the adoption of smart panels in older properties is a significant step towards more efficient power management, the process isn't straightforward. As discussed above, there are numerous challenges to overcome in order to truly leverage the capabilities of these smart panels and achieve the level of efficiency, control, and safety that a modern ‘smart’ electrical system can offer.

A feature-wise comparison of some known products in the market is shown in Table 1 below:

TABLE 1

| Feature description | Product 1 | Product 2 |
|---|---|---|
| Quick single-line tracing | Residential | No |
| | low voltage | |
| | application only | |
| Result Notification | Basic | Basic |
| | Beeping only. | No beeping. Basic |
| | No circuit number | circuit number |
| | or any other | display only. |
| | circuit-related | There is no |
| | information is | advanced display |
| | displayed. | of all circuit- |
| | | related information. |
| Additional load tracing | Yes - light loads | Yes - light loads |
| transmitters connectable | only, e.g., | only, e.g., light |
| with adapters to | light switches | switches and |
| other loads | and fixtures | fixtures |
| Tracing multiple loads on | No | Yes |
| a single power line | | |
| Multiple panel mapping | No | No |
| Automatic panel, equipment, | No | No |
| device label generation | | |
| Digital result | No | No |
| recording/cloud storage | | |
| Digital twin creation | No | No |
| Integration with Smart | No | No |
| Mobile Label printers, | | |
| e.g., Brady & Brother | | |
| Automatic circuit directory | No | No |
| creation with file export, | | |
| e.g., PDF, XLS, JSON format | | |
| Integration with Smart | No | No |
| Mobile Printer/Thermal | | |
| Printer | | |
| Nonconnected wireless | No | No |
| communication of results, | | |
| e.g., Wi-Fi | | |
| beacons/timestamps | | |
| Instant Plug outlet | No | No |
| testing for wiring | | |
| condition (plug tester) | | |
| Viable for large properties | No | No |
| Other Load Tracing Non- | No | No |
| connected (Light Switch, | | |
| terminated line) NCV | | |
| detection | | |
| Verified results without | No | No |
| power cycling | | |
| Connected blinker | No | No |
| communication of results | | |
| via, e.g., Bluetooth | | |
| to phone, cellular | | |
| network to cloud) | | |
| Connected power monitoring, | No | No |
| e.g., Hub to Wi-Fi | | |
| or cellular | | |
| Can be left in permanently | No | No |
| for Power Monitoring | | |
| Simple CT install (power | No | No |
| bar with mag connect low | | |
| voltage or self-charge) | | |
| Load blinking on switch | No | No |
| lamp/fixtures (adapters) | | |

Product 1, puts an electronic transmitter signal on the powerline by plugging into a receptacle outlet that can be detected at the source with an electronic non-contact receiver. One drawback, however, with this product may be that it is susceptible to back-feeding conditions that could produce inaccurate results when more than one transmitter is used at a time, when distances are long, or when electrically neutral lines from various circuits are mixed. Performing a test on unknown electrical circuits and networks using such products may lead to electrical shocks or unplanned disruptions of the critical systems if not grounded properly. Also, this product may not be usable where multiple panels are to be mapped to an electrical network, as it cannot verify results without power cycling.

Product 2 is similar to a conventional circuit breaker in that it does what a breaker finder does but is designed to operate in reverse order, i.e., by transmitting electronic signals from the source to the load. It also allows these signals to be transmitted from multiple lines while using a full-contact plug-in receiver that also contacts the physical live power line at the load end. This allows for multiple lines to be tested, but only a single panel can be mapped at a time. The user works live by connecting transmitters to individual live branch lines or the live terminals of the breakers, while the device also has a basic receiver that merely displays a breaker number. The use of this device merely replicates the manual identification of power lines at best, which is also cumbersome to perform.

Hence, there is a need for a power monitoring system and method to overcome the drawbacks of known systems such as those discussed above. It would also be prudent to develop the power monitoring system such that it could be used as a tool to digitize line and load information of an electrically networked system. Persons skilled in the art would also appreciate it if the developed power monitoring system could continually remain installed onto the electrically networked system to serve as a digital twin of the system. This would not only render the developed power monitoring system ‘smart’ at the start of its use in mapping but also continually maintain the ability to provide monitoring of power lines while it is in operation, thereby creating a digital twin of the electrically networked system and whereby monitoring of electrical loads on the electrically networked system can be carried out with maximum safety to users without the need for extensive manual intervention.

### SUMMARY

In one aspect of the present disclosure, there is provided a system for tracing and monitoring power lines of electrical networks. In an embodiment, the system comprises a first device that may be configured to be a transmitter and connected to a power line. The first device transmits at least one signal that is associated with an amplitude, a phase, a frequency, a switching frequency and a duty cycle of current including a plurality of current signatures. The plurality of current signatures include an unique first current signature associated with the first device and at least one second current signature associated with one or more load fixtures connected on a power line. In an embodiment, the at least one signal is transmitting by one or more of a plurality of metal-oxide-semiconductor field-effect transistors (MOSFETs), a plurality of bipolar junction transistors (BJTs), a plurality of insulated-gate bipolar transistors (IGBTs), a plurality of relays, a plurality of triacs to modulate a load and current of the power line.

Further, the system includes a second device that may be configured to a receiver and connected to a circuit breaker switch disposed upstream of the first device and located on an electrical panel. The second device is in communication with the transmitter of the first device to receive the at least one signal therefrom. The system further includes a power monitoring system in communication with the receiver of the second device. The power monitoring system comprises a processor configured to process the at least one signal received at the second device using Fast Fourier Transform (FFT) including the current signatures for obtaining the unique first current signature of the first device and the at least one second current signature associated with the one or more load fixtures.

Further, the power monitoring system may send at least one signal from the receiver to the transmitter to confirm whether the power line on which the one or more load fixtures are connected is the power line that is connected to the circuit breaker. Further, the power monitoring system may determine whether total current input to the power line via the circuit breaker matches with a sum of currents to the transmitter and the one or more serially or parallelly connected load fixtures located downstream of the transmitter as indicated from data contained in the at least one signal communicated by the transmitter to the receiver. Further, the power monitoring systems may generate user intelligible data representation of the confirmation and determination.

In an embodiment, the power monitoring system may be enabled to differentiate the signals that may be transmitted or received. For example, when multiple components such as wall outlets or circuit breakers send signals simultaneously or in quick succession, the power monitoring system may generate timestamps corresponding to each signal. The timestamps may enable differentiating the signals and order the signals based on the exact time they were sent or received. This may be done automatically at the CT without a user intervention on load blinker's end.

In an embodiment, the power monitoring system may execute operations to log events in the system. For instance, the power monitoring system may execute operations to detect any anomalies or significant events detected based on the timestamps. The timestamps may provide a precise record of when these events occurred. This can be crucial for troubleshooting or analyzing the system's performance over time.

In an embodiment, the power monitoring system may execute operations to enable synchronization. For instance, when there are multiple devices or components in the system, timestamps may enable or provision the components function or operate in a synchronized manner. For example, when a signal is sent from a wall outlet and is to be processed by multiple components of the system, timestamps can help coordinate this process.

In an embodiment, the power monitoring system may enable performing analysis on the data that may be logged. For instance, component level performance metrics may be analyzed. For example, the timestamps may be used to measure the time taken for certain operations, like the time interval between a signal being sent from a wall outlet and its corresponding circuit breaker being identified.

In an embodiment, the system may include one or more CTs configured to operate or function as a PLC receiver(s) and One or more impedance load(s) as transmitter(s). Further, the system may include one or more CTs configured as a PLC receiver(s) and one or more potential transformer(s) configured as transmitter(s). Further, the system may include one or more PT's that may be configured as PLC receiver(s) and one or more CT(s) configured as transmitter(s). Further the system may include one or more PT's configured as a PLC receiver(s) and one or more impedance load(s) configured as a transmitter. Further, the system may be configured to be operated in a combination of all of the above described configurations.

In another aspect of the present disclosure, there is provided a method for tracing and monitoring power lines of electrical networks. The method includes connecting a receiver to a power line at a location adjacent to a circuit breaker switch disposed on an electrical panel. The method further includes connecting a transmitter to the power line adjacent to one or more serially or parallelly connected load fixtures located downstream of the transmitter and communicate at least one signal pertaining to amplitude, phase, frequency, switching frequency and duty cycle of current with a combined unique current signature from the transmitter itself as well as from the one or more load fixtures with the receiver. The method further includes providing a power monitoring system, comprising a processor, in communication with the receiver. The method further includes processing, using the processor, the at least one signal received at the receiver using Fast Fourier Transform (FFT) on the combined unique current signature for obtaining a first unique current signature of the transmitter and at least one second current signature pertaining to the one or more load fixtures.

In an embodiment, the method further includes the steps of sending, using the processor, at least one signal from the receiver to the transmitter to confirm whether the power line on which the one or more load fixtures are connected is the power line that is connected to the circuit breaker. The method further includes the step of determining, using the processor, whether total current input to the power line via the circuit breaker matches with a sum of currents to the transmitter and the one or more serially or parallelly connected load fixtures located downstream of the transmitter as indicated from data contained in the at least one signal communicated by the transmitter to the receiver. The method further includes the step of generating, using the processor, user intelligible data representation of the confirmation and determination.

In yet another aspect of the present disclosure, embodiments disclosed herein are also directed to a non-transitory computer readable medium having stored thereon computer-executable instructions which, when executed by a processing unit, causes the processing unit to perform steps of the method disclosed herein.

This disclosure presents a self-identifying and self-calibrating system and method for monitoring power of an electrical networks of a pre-existing, or ageing, building by tracing power lines through power load modulation and machine learning powerline detection. The present disclosure is described with reference to a pre-existing, or ageing, building. However, the skilled person will understand that the present disclosure is not restricted to such a structure. On the contrary, the present disclosure is applicable to any environment or facility in which electrically networked systems are present to drive electrical loads.

Further, the system and method addresses the problem of accounting for undetected loads on electrically networked systems. In this way, the system and method of the present disclosure can facilitate a more accurate detection, identification and estimation of loads and breakers on electrically networked systems without the need for power cycling. Accordingly, the power monitoring system of the present disclosure has a “Self-identification” ability to automatically identify and categorize different elements of the system (like circuits and loads), even in complex and previously undocumented electrical infrastructures.

It will be appreciated that features of the present disclosure are susceptible to being combined in various combinations without departing from the scope of the present disclosure as defined by the appended claims.

### BRIEF DESCRIPTION OF THE DRAWINGS

The summary above, as well as the following detailed description of illustrative embodiments, is better understood when read in conjunction with the appended drawings. For the purpose of illustrating the present disclosure, exemplary constructions of the disclosure are shown in the drawings. However, the present disclosure is not limited to specific methods and instrumentalities disclosed herein. Moreover, those in the art will understand that the drawings are not to scale. Wherever possible, like elements have been indicated by identical numbers.

FIGS. 1A and 1B are illustrations showing deployment of a power monitoring system and a load blinker, according to an exemplary embodiment.

FIG. 2 is an illustration showing documents including technical information that are generated by a blinker mapping mechanism of the power monitoring system, according to an exemplary embodiment.

FIG. 3 is a block diagram showing an illustration of a load mapping, according to an exemplary embodiment.

FIG. 4 is an illustration showing advantages of power mapping upon completion of the load mapping process, by the smart monitoring system, according to an exemplary embodiment.

FIG. 5 is an illustration showing implementation of the power monitoring system for automated maintenance scheduling, energy savings, and anomaly detection, according to an exemplary embodiment.

FIG. 6 is an illustration showing a deployment of smart electrical system, according to an exemplary embodiment.

FIG. 7 is an illustration showing an environment that may be monitored by the power monitoring system, according to an exemplary embodiment.

FIG. 8 is an illustration showing a graph that is generated based on an implementation of multiple digital filtering techniques by the power monitoring system, according to an exemplary embodiment.

FIG. 9A and FIG. 9B are illustrations showing an implementation of the power monitoring system automating the identification of wall outlets connected to specific circuit breakers, according to an exemplary embodiment.

FIG. 10A and FIG. 10B are illustrations showing an implementation of the power monitoring system automating the identification of wall outlets connected to specific circuit breakers, according to an exemplary embodiment.

FIG. 11A and FIG. 11B are illustrations of a dual function current transformer implemented by the power monitoring system, according to an exemplary embodiment.

FIG. 12A and FIG. 12B are illustrations showing an implementation of analog and digital filtering techniques implemented by the power monitoring system, according to an exemplary embodiment.

FIG. 13 is an illustration showing the load blinker with an intuitive plug outlet tester, according to an exemplary embodiment.

FIG. 14 shows an illustration of live line detection circuit, in accordance with an exemplary embodiment.

FIG. 15 is an illustration showing a high level diagram of how a live line detector detects load blinker on the line when noise is present, according to an exemplary embodiment. FIG. 16 is an illustration showing a high level diagram of the power monitoring system generating maintenance logs, according to an exemplary embodiment.

FIG. 17 is an illustration of a circuit that implements Kirchoff's Current Law, according to an exemplary embodiment.

FIG. 18 is an illustration showing main responses for event flagging, according to an exemplary embodiment.

FIG. 19 is an illustration showing inrush current events, according to an exemplary embodiment.

FIG. 20 is an illustration showing undamped system's inherent oscillation rate, according to an exemplary embodiment.

FIG. 21 is an illustration showing movement of poles on a s-plane, according to an exemplary embodiment.

FIG. 22 is an illustration showing current during an inrush current event, according to an exemplary embodiment.

FIG. 23 is an illustration showing overshoot percent computed using computational method, according to an embodiment.

FIG. 24 is an illustration showing computations of natural frequency, according to an exemplary embodiment.

FIG. 25 is an illustration showing a graphical representation of the inrush current phenomenon, according to an exemplary embodiment.

FIG. 26A and FIG. 26B is an illustration showing a flow diagram of operational logic of computer executable code implemented by the power monitoring system, according to an exemplary embodiment.

FIG. 27A and FIG. 27B are illustrations showing graphical representations underdamped and critically damped system, according to an exemplary embodiment.

FIG. 28 is an illustration showing effect of natural frequency and damping ratio on behavior of an electrical equipment, according to an exemplary embodiment.

FIG. 29A and FIG. 29B are illustrations showing belt malfunctions, according to exemplary embodiments.

FIG. 30 is an illustration showing high level raw FFT to output of the idealized load blinker, according to an exemplary embodiment.

FIG. 31A and FIG. 31B are illustrations showing frequency and amplitude distributions, according to exemplary embodiments.

FIG. 32A and FIG. 32B are illustrations showing distribution of amplitude and frequency for FFT output, according to exemplary embodiments.

FIG. 33A and FIG. 33B show illustrations of logarithmically scaled frequency output, according to exemplary embodiments.

In the accompanying drawings, an underlined number is employed to represent an item over which the underlined number is positioned or an item to which the underlined number is adjacent. A non-underlined number relates to an item identified by a line linking the non-underlined number to the item. When a number is non-underlined and accompanied by an associated arrow, the non-underlined number is used to identify a general item at which the arrow is pointing.

### DETAILED DESCRIPTION OF ILLUSTRATIVE EMBODIMENTS

The following detailed description illustrates embodiments of the present disclosure and ways in which they can be implemented. Although the best mode of carrying out the present disclosure has been disclosed, those skilled in the art would recognize that other embodiments for carrying out or practicing the present disclosure are also possible.

For purpose of the present disclosure, the terms below have their respective meanings.

Power line communication (PLC)—A technology that allows power lines to be used for data communication by transferring data over existing power lines.

Potential transformer (PT)—A type of transformer typically used for changing voltages seamlessly, or in discrete amounts, while maintaining direct electrical isolation. This type of transformer is typically connected from live to neutral and can be used in a PLC technology application, such as the power monitoring system of the present disclosure, for generating a signal at a selected frequency.

Current Transformer (CT)—A device that measures AC current by inducing a smaller current from a primary coil into a secondary coil such that it is low enough to read the voltage drop across a shunt resistor in proportion to the current running through it.

Load Modulation—A unique current signature that can be obtained by using unique impedance loads from the potential transformer that are connected from live to neutral.

Phase Modulation—A form of modulation, using an inductive or capacitive load to apply a phase change within a current of the signal being modulated.

Amplitude modulation—Form of modulation, using varying resistive, inductive or capacitive loads to modulate the magnitude of the current draw.

Switching Frequency Modulation—For the purposes of this disclosure, frequency (also called switching time) is indicated by the time it takes a load to be turned ON and OFF or vice versa, or the time to switch between loads. This switching time is adjusted i.e., increased or decreased to suit specific requirements of a modulation scheme or application.

Pulse Width Modulation (PWM)—A form of modulation where it modulates the duty cycle, the ON time. For example, the load could be ON for 20% of the time, then increased to 40% of the time, subsequently to 60% of the time or more. Likewise, the modulation could define the off as a different load.

Light Switch Impedance Modulation—Modulating the switch to mechanically actuate and electrically turn ON or OFF a load associated with a load fixture e.g., a light bulb on a bulb socket. Modulating the light bulb's line impedance at a steady frequency or amplitude.

Machine learning (ML) refers to a branch of artificial intelligence (AI) and computer science which involves implementing execution of routines and algorithms to execute specific operations. Such operations may include processing data, learning from data and identifying data patterns. Based on the learning the machine leaning engines may efficiently execute operations by gradually improving its accuracy.

Grey Box Model refers to an approach in computational modeling where the system being modeled is neither entirely transparent (e.g., a white box or an uncolored clear box) nor entirely opaque (e.g., a black box). In a grey box model, some information about the internal workings of the system is known. The parts that are known and can be directly observed or influenced are considered the “white” parts, and the parts that are hidden or unclear are considered the “black” parts.

Fast Fourier Transform—The Fast Fourier Transform (FFT) is an algorithm that computes the discrete Fourier transform (DFT) of a sequence, or its inverse, in an efficient manner. Fourier analysis converts a signal from its original domain (often time or space) to a representation in the frequency domain and vice versa.

As will be explained in detail later herein, the power monitoring system of the present disclosure can be configured using any of the following configurations: One or more Current Transformer(s) (CT(s)) to act as PLC receiver(s) and one or more impedance load(s) configured as PLC Transmitter(s); one or more CT(s) configured as PLC receiver(s) and one or more Potential Transformer(s) configured as PLC Transmitter(s); one or more CT(s) configured as PLC receiver(s) and one or more CT(s) configured as PLC Transmitter(s).

In an embodiment, the receiver may be a power monitoring system may be communicatively coupled with, for example, Current Transformers (CTs), internet connectivity, and machine learning capabilities that provides detailed, real-time insights into power usage. One of the objectives of employing the current transformers (CTs) is to enhance a degree of control over electrical systems, to facilitate gains in energy efficiency, and thereby reduce energy costs. However, in order to do so, the CTs are configured to first identify themselves to provide the highest quality of data about the electrical system back to the property manager.

In various embodiments, the power monitoring system performs modulation of at least one of amplitude, phase, frequency, switching frequency, and duty cycle to generate unique current signatures for power source identification. The power monitoring system thereafter may implement an execution of algorithms or operations related to, for example, Fast Fourier Transform (FFT), Machine Learning (ML), and a grey box model. Such an implementation may provision execution of operations, for example, performing analysis to identify those unique current signatures. In some embodiments, the power monitoring system may implement execution of CT(s) to transmit the unique current signatures with PLC back to the wall socket and light switch panel to the device to communicate a received confirmation.

In an embodiment, the power monitoring system may include hardware components or hardware units. The main hardware components may include a power monitor that connects directly to an electrical panel, and multiple CTs. The power monitor is often a compact device designed to fit within or close to the electrical panel. CTs are devices that clamp onto the electrical wires entering each circuit breaker, thereby monitoring the electrical current flowing through each circuit without disrupting it.

In an embodiment, the power monitoring system may further include Current Transformers (CTs). CTs transform the current flowing through the wire they are clamped to into a smaller, proportional current that can be measured by the monitor. The CTs are designed to enable easy installation without the need for circuit interruption.

In an embodiment, the power monitoring system may further include a high-frequency sampler. The power monitoring system may have the ability to adjust its sampling frequency to provide more granular data. High-frequency sampling can capture quick changes in power usage, making it possible to identify transient events or anomalies that might otherwise be missed and can be used to identify the load blinker with speed and accuracy.

In an embodiment, the power monitoring system may further implement an execution of machine learning framework. The machine learning framework may enable the power monitoring system to continually learn and recognize the unique power consumption patterns of specific loads over time. Users can set custom characteristics for the power monitoring system to identify and monitor such custom characteristics. Once these characteristics are learned, the power monitoring system may execute operations to automatically detect the operation of these specific loads, track usage, and predict performance related attributes or parameters. Additionally, the power monitoring system may implement the fast fourier transform algorithms to improve the machine learning ability to detect load blinker.

In an embodiment, the power monitoring system may include a communication or connectivity module or engine. The power monitoring system may be configured to communicate via the Internet, generally through Wi-Fi or Ethernet, thereby enabling it to transmit collected data to a remote server or cloud-based platform. This facilitates real-time monitoring and control of power usage from any location, via any internet-enabled device thereby enabling real-time feedback to inform the user that the blinker has been identified on the line and it is safe to unplug and move to the next line.

In an embodiment, the power monitoring system may include an implementing of a software application or a mobile application. For example, the software application or the mobile applications may be configured to execute operations as a power mapping wizard. Further such applications may enable entering data manually into the power monitoring system in a user-friendly format. After the calibration the additional features may include real-time power usage displays, historical data trends, predictive analytics, and customizable alerts for unusual power usage or system faults.

In an embodiment, the power monitoring system may enable energy management. Detailed insights from the power monitoring system may enable users identify inefficiencies or anomalies in power usage, informing energy-saving measures and maintenance scheduling. The high-frequency sampling and machine learning framework may enable precise energy management and potentially earlier detection of issues.

In an embodiment, the power monitoring system may provision or enable users an in-depth view of their energy consumption, thereby providing valuable information to guide energy conservation strategies, system maintenance, and overall property management decisions. Machine learning framework may further enhances learning and training capabilities thereby adding a layer of intelligence that can adapt and respond to specific user-defined characteristics.

In an embodiment, the transmitter is a device that a user would connect to a wall socket and or light switch. The transmitter could be embodied as a load blinker, or a light blinker. The load blinker may execute operations to transmit a signature such that the CT could identify the source of this signal based on an identification of a timestamp indicating the time the signal was transmitted and the unique current signature characteristics (e.g., amplitude, phase, frequency, switching frequency, duty cycle, etc.) associated with it that the CT received. In an embodiment, the signal may be transmitted by multiple components. For example, such components may include metal-oxide-semiconductor field-effect transistors (MOSFETs), a bipolar junction transistors (BJTs), insulated-gate bipolar transistors (IGBTs), relays, TRIACs. The above described components may modulate the load and current of the power line.

In another embodiment, for power source identification, the transmitter is used on the live line to identify other circuits connected in parallel to the transmitter as a “sounding method” with a grey box, white box or black box computational approach. In such embodiment, the transmitter may be configured to identify itself and a specific device that may be present, or that specific problems that may be associated with the specific device. This could include the transmitter using information about the identified current signature and comparing with the known device on the line, i.e., the load blinker with other potential information such as scanned panel cards for electrical and or mechanical information with the parsed information to gather information of the current draw signature of potential devices on the line.

In an embodiment, the above described mechanism implemented by the power monitoring system may deduce an association of wall sockets of any voltage and circuit breaker within a circuit panel, without having to power down the overall network or system. by implementing a current monitoring system such that the receiver uses the CTs, to a live wire coming out from the circuit breaker, in a permanent or semi-permanent manner. The CTs of the current monitoring system may be configured to measure the current drawn on the line, specifically, these CTs ‘listen’ to the load blinker device that is attached to the wall socket. The load blinker does may include impedance elements that can be cycled ON and OFF and the modulation schemes.

In an embodiment, the above described mechanism may be implemented by one or more circuit breakers simultaneously. With multiple circuit breaker panels, the power monitoring system may use one or more load blinkers and or light blinkers to transmit back to the CT which functions or operates as a receiver. In such a scenario, a single power monitoring system may be required to identify and transmit the signal.

In an embodiment, the current monitoring system may be configured to read the current signature and process the data such that it could detect for the unique signature of the load blinker or light blinker.

In an embodiment, the power monitoring system may incorporate such that the receiver may transmit a signal back to the load blinker and or light blinker to give a confirmation message. The power monitoring system may implement wireless communication methods such as Bluetooth, WiFi, LoRa, etc., to communicate a confirmation message. Alternatively, the integrated current transformer could reverse polarity to give a readable signal with PLC style of messaging. In addition, a dedicated potential transformer at the current reading side could transmit this signal. Any PLC method could cover this confirmation and transmission for the express purpose of power source identification.

In an embodiment, the power monitoring system may further include a display. For example, an user-interface of a mobile phone or a smartphone may be configured to provision a user interface that would enable a manual and/or automatic collection of system information to be collected during the self-calibration, self-identification, self-digitization process of the system information collection regarding the lines and loads of the electrical system.

In an embodiment, the power monitoring system may be deployed to operate or function, such as entering locations as to where the load or light blinker is being plugged in such as: type of load, room, floor, building. Further, power monitoring system may enable capturing images via phone camera and implement machine learning engines or framework for image recognition. Such image recognition may enable collecting the equipment rating plates to collect load information such as serial numbers, model numbers and other equipment information that would normally be identified on a rating plate. The power monitoring system may enable capturing images via phone camera and implementing machine learning engines or framework for determining schematic prints, floor plans, circuit diagrams, or any other technical documentation related to the system. Further such information or data may be digitized and modified in real-time. Or parse it and use it for referencing the system and the property it is installed in. Floor plans contain valuable information regarding a building's structure, layout, and utility systems, including the electrical system.

In an embodiment, information related to the equipment and the electrical system that can typically be found on a floor plan may include equipment as shown in Table 2 below.

TABLE 2

| Type of Electrical | |
|---|---|
| Equipment | Placement of the Electrical Equipment |
| Equipment Layout | This includes the placement and footprint of |
| | large pieces of equipment such as HVAC |
| | systems, electrical panels, generators, |
| | elevators, large kitchen appliances, etc |
| Electrical Outlets | The locations of all electrical outlets, |
| and Fixtures | light fixtures, switches, and any other |
| | components of the electrical system. |
| Electrical Panels | The floor plan usually marks the |
| and Circuit | locations of electrical panels and |
| Breaker Locations | circuit breakers. |
| Wiring Routes | While not always included in a basic floor |
| | plan, more detailed plans may show the |
| | routes of electrical wiring throughout the |
| | building. |
| Electric Load | Areas that have high power consumption |
| Centers | (like server rooms, kitchens, etc.) might be |
| | specially marked. |
| Special Electrical | Any specialized electrical equipment (such as |
| Equipment | transformers, generators, or uninterruptible |
| | power supply systems) will also typically be |
| | marked on a detailed floor plan. |
| Emergency Exits | The placement of emergency exits and |
| and Lighting | emergency lighting fixtures, which are |
| | important parts of a building's safety |
| | infrastructure. |
| Safety Equipment | The locations of fire extinguishers, fire |
| | alarms, and other safety equipment; |
| Service Entries | Locations where utilities (including |
| | electricity) enter the building. |
| Ratings of Major | The floor plan might contain information |
| Equipment | about the capacity or ratings of major |
| | electrical equipment. |

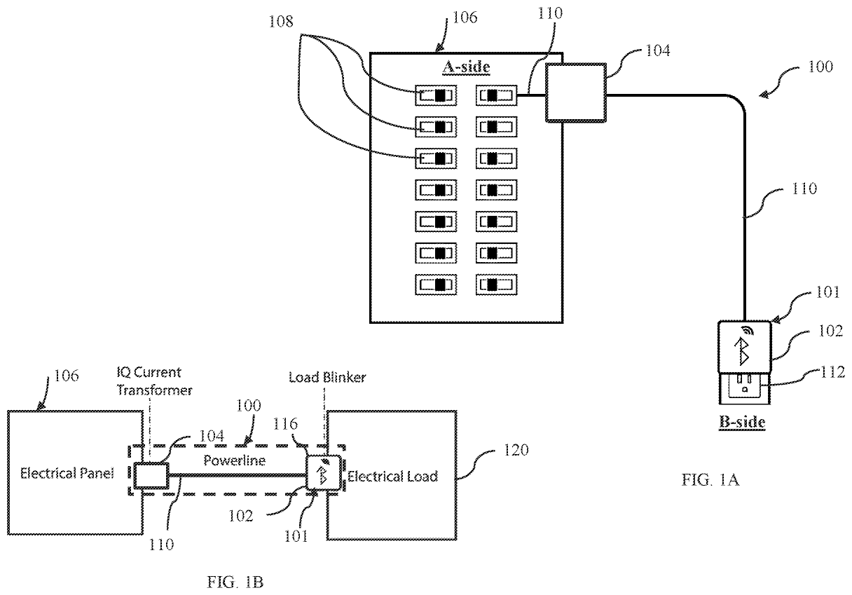

FIGS. 1A and 1B are illustrations showing a deployment of a power monitoring system and a load blinker, according to an exemplary embodiment. With reference to FIG. 1A, there is shown a system 100 that includes a communicatively coupled arrangement of a load blinker 102 that may be plugged into a power line 110 (e.g., via an exemplary wall socket 112) and the CT 104 that may be configured to monitor the line 110 and detect a presence of the load blinker 102. FIG. 1A shows that the CT 104 is disposed towards a source side (A-side) of the feed and the load blinker 102 is disposed towards the load side (B-side). It may be noted that, in embodiments herein, the load blinker 102 may be configured as, for example, a first device that may include a transmitter as best shown using reference numeral ‘118’ in FIG. 1B.

Referring to FIG. 1B, there is shown that the CT 104 that is plugged into an electrical panel 106 and the load blinker 102 is connected to an electrical load fixture 120. Referring back to FIG. 1A, the CT 104 is connected to, or adjacent to, a circuit breaker 108 within the electrical panel 106 and the load blinker 102 is disposed at, or adjacent to, an electrical load fixture 120. It may be noted that, in embodiments herein, the monitoring system 104 may be configured as, for example, a second device 101 having a receiver.

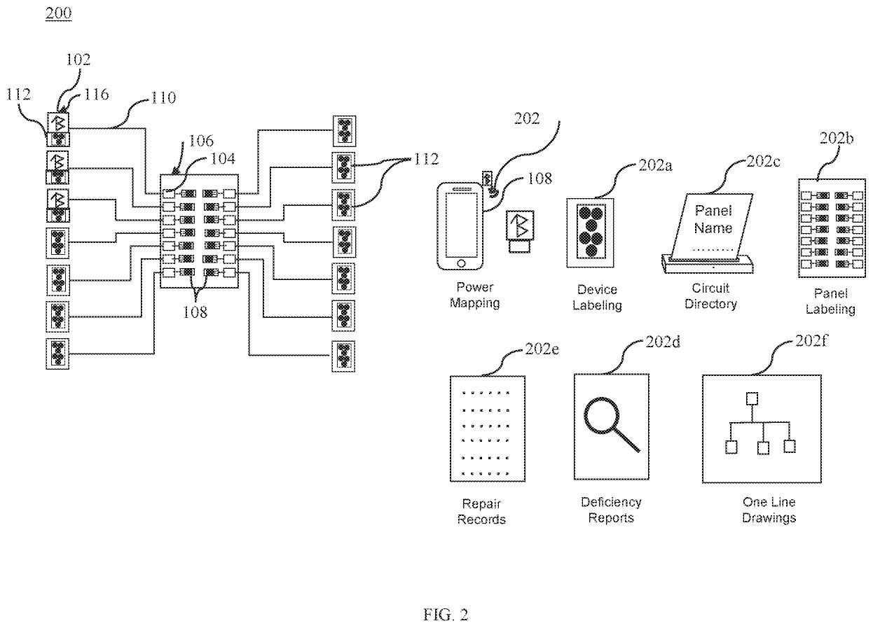

FIG. 2 is an illustration showing documents including technical information that are generated by a blinker mapping mechanism of the power monitoring system, according to an exemplary embodiment. With reference to FIG. 2, there is shown an illustration of the power monitoring system implementing blinker mapping mechanism or process. The power monitoring system may implement a process or mechanism such that the disposition of the load blinker 102 is moved in a definite sequence. For example, mechanism may include a movement of disposition of the load blinker 102 from one socket 112 to another (e.g., shown as series 1, 2, 3. and so on in FIG. 2) with the deliverables that may be generated upon completion of the blinker mapping process. For example, a property e.g., a facility, a building and other types of properties may not have any technical documents related to the power line. By implementing the blinker mapping process, multiple reports including information or data may be generated.

In an embodiment, the power monitoring system 104 implementing the blinker mapping process may include the load blinker 102 relaying or sending the electrical properties of the circuit being monitored, and an IoT device 202, for example, a mobile phone that is additionally, or optionally, provided to the blinker mapping system 200. The IoT device 202 may include, for example, a processor, a memory, a graphical user interface (GUI) and a wireless network communication module to remotely communicate with an IoT module of the first device 116. The IoT device 202 may be used to capture, store and display information pertaining to for example, equipment/device labels 202a, panel labels 202b, circuit directories 202c, electrical safety deficiency reports 202d, repair records 202e, and electrical one-line drawings 202f. In an embodiment, for any anomalies or significant events detected by the power monitoring system, timestamps may be provide a precise record of when these events occurred. This can be crucial for troubleshooting or analyzing the power monitoring system's performance over time.

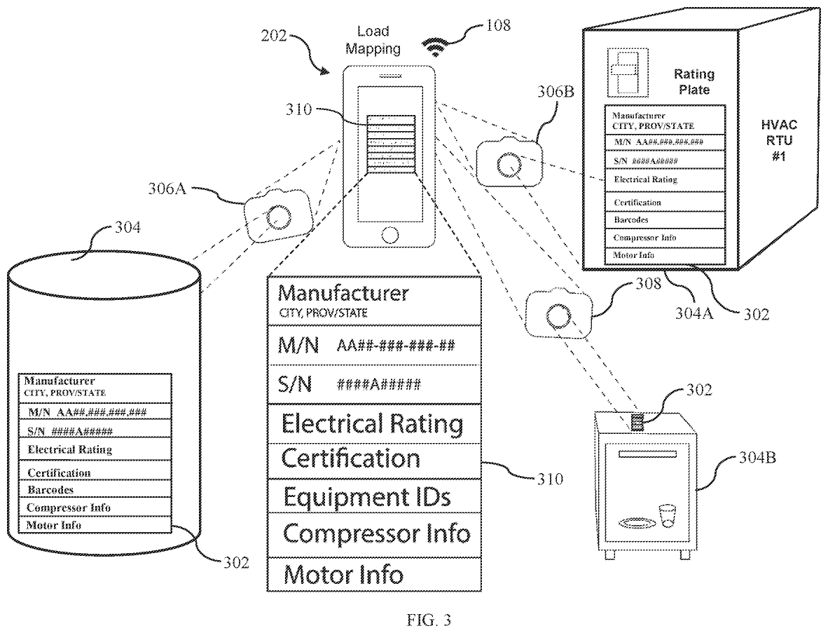

FIG. 3 is a block diagram showing an illustration of a load mapping, according to an exemplary embodiment. FIG. 3 illustrates a mechanism for load mapping that is executed by the power monitoring system. In an embodiment, images and/or scans of rating plates 302 on any device/piece of an electrical equipment 304 may be captured using the IoT device 202. As shown in FIG. 3, the IoT device 202 may include a camera 306A, and/or an image sensor 306B and/or a image scanner 308. For example, a digital camera and/or a Quick Response (QR) code scanner may be included within a configuration of the IoT device 202 to facilitate capturing images and/or scans. Information on these rating plates may be extracted by parsing the captured image/scan via image recognition techniques for any relevant unique identifiers or other types of equipment related identification codes (for example, related to performance or safety). In an embodiment, the process or mechanism of capturing and storing information pertinent to electrical loads is hereinafter referred to as ‘load mapping’ as shown exemplarily and denoted using reference numeral 310 in FIG. 3. If there are multiple devices or components, the timestamps generated by the power monitoring system may enable executing operations in a synchronized manner. For instance, if a signal is sent from a wall outlet and is to be processed by multiple components of the system, timestamps may enable coordination of the above described processing.

In an embodiment, the property owners and electrical workers/technicians may not be fully aware of the maintenance, upgrade, or replacement schedules for their electrical equipment. This lack of awareness can lead to inefficiencies, with facilities experiencing a reduction in productive capacities of up to, for example, 20% or more due to inadequate, or ineffective, maintenance strategies. Predictive maintenance in factories may enable numerous benefits including substantial reduction in costs, improvement in up-time, decrease in quality and risks associated with safety, health, and environment while also extending a remaining useful life (RUL) of such aging assets.

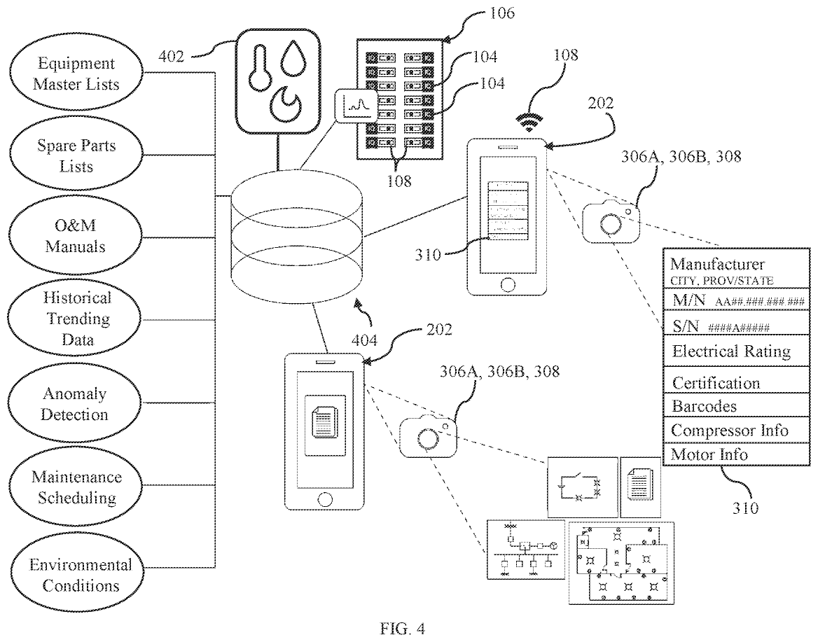

FIG. 4 is an illustration showing advantages of power mapping upon completion of the load mapping process, by the smart monitoring system, according to an exemplary embodiment. FIG. 4 is described in conjunction with FIG. 3. With reference to FIG. 4, there is shown an illustration including the benefits or advantages of power mapping once the load mapping has been completed. In an embodiment, the power monitoring system may complete the load mapping process using online resources and other monitoring systems. Once line and load mapping is completed, technical reports or a collection of documents may be generated by the power monitoring system. For example, the documents may contain information related to equipment master lists, equipment slave lists, spare parts lists, operations and maintenance (O & M) manuals, historical trending data, anomaly detection, scheduling of maintenance activities, and other environmental conditions.

In addition, the documents generated by the power monitoring system may also contain certain information that may be gathered or assimilated from online resources, for instance, in the case of an electrical equipment having its performance and/or safety rating being implemented by way of a QR code captured using the camera 306 of the IoT device 202. In other embodiment, the power monitoring system could be used in conjunction with other environmental sensors 402, for example, temperature sensor, a humidity sensor, and other types of sensors known to persons skilled in the art and deployed on site.

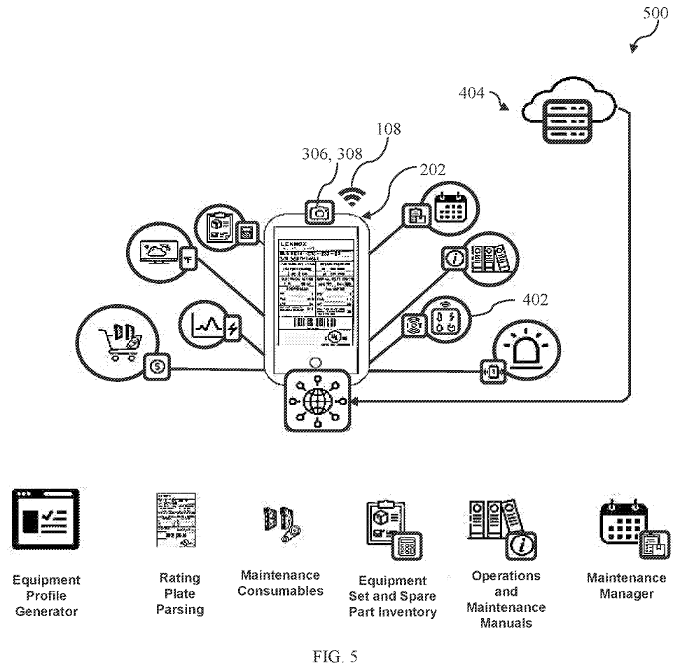

FIG. 5 is an illustration showing implementation of the power monitoring system for automated maintenance scheduling, energy savings, and anomaly detection, according to an exemplary embodiment. FIG. 5 is described in conjunction with FIG. 2 and FIG. 4. With reference to FIG. 5, there is shown an illustration that depicts how the rating plate information may be used for generating equipment periodic maintenance schedules, logs and checklists. In an embodiment, the IoT device 202 may be coupled to an online server 404 that hosts a mobile, or web, application on the IoT device 202 that is user friendly to the property owner, the electrical worker or the technician. Moreover, the IoT device 202 uses rating plate data for facilitating automated maintenance scheduling, automated control strategies for energy savings, and anomaly detections. In the example of FIG. 5, the rating plate information can be used to parse the Internet for Operations & Maintenance (O & M) manuals, and the manuals can be further be parsed to gather key information and generate equipment planned maintenance (PM) schedules, logs & checklists, equipment profiles, maintenance consumables, spare parts lists, inventory quantity counts, expected load ratings and other relevant data pertinent to electrical properties and consumables of the mapped load and line. In an embodiment, the timestamps may provide users with the exact time of the event, enabling the users to take timely action and make informed decisions. The IoT device 202 may operate or function act as a visual/graphical user interface (GUI) to help a property owner or an electrical worker/technician to visualize the electrical properties and consumables of the mapped load and line.

In an embodiment, the IoT device 202 may include an auto scheduler module that is configured to virtually build maintenance schedule on digital calendars based on recommendations in the O & M manual. Further, any anomalies detected by the power monitoring system enables implementing a reactive maintenance approach i.e., rescheduling a maintenance schedule as required. In some cases, a difference between optimized runtime due to early maintenance and a regular scheduled maintenance date can be regarded as energy savings.

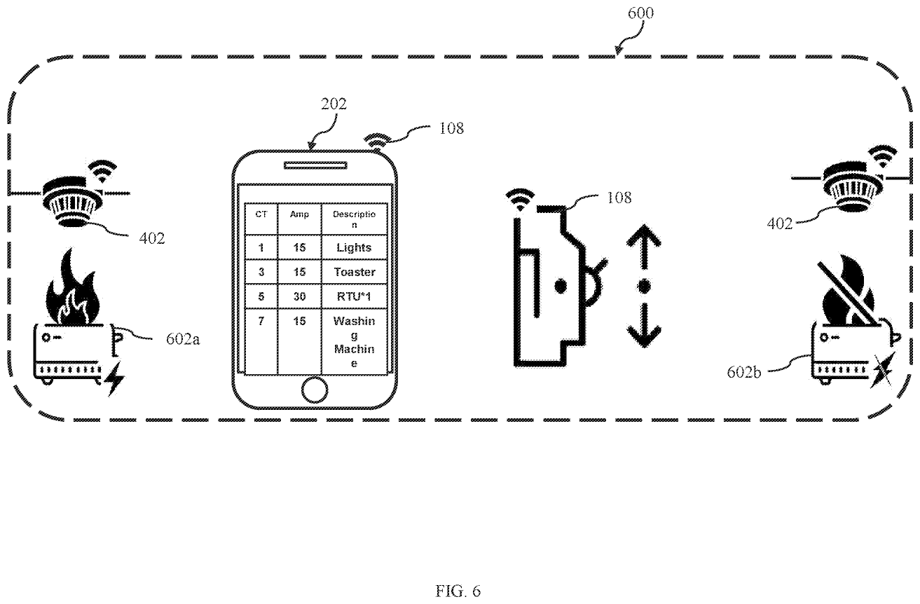

FIG. 6 is an illustration showing a deployment of smart electrical system, according to an exemplary embodiment. FIG. 6 is described in conjunction with FIGS. 1A-1B and FIG. 2. With reference to FIG. 6, there is shown an environment 600 including a deployment of smart electrical system. In an embodiment, FIG. 6 illustrates a fully mapped electrical system that may include, for example, remote management and remote control, fire detection capabilities, and pre-emptive safety action capabilities. In an example, the mapped electrical system may be integrated with an environmental sensor, for example, sensor 402 for detecting smoke to indicate presence of fire and a breaker that can be remotely controlled, for example, via Bluetooth, Wi-Fi or another long or short range wireless communications protocol. From the preceding example, it can be envisioned that if the sensor 402 detects smoke on a line having a toaster 602a plugged and sends a detection signal to the server 404 (refer to FIGS. 4-5), the server 404 can shut-off power by controlling the circuit breaker 108 corresponding to the line on which the toaster 602a is plugged and not other circuits on which other cooking related equipment 602b may be present. The online server 404 can be configured to provide such remedial actions e.g., trip the circuit breaker 108 to the toaster 602a as a pre-emptive solution to minimize the fire.

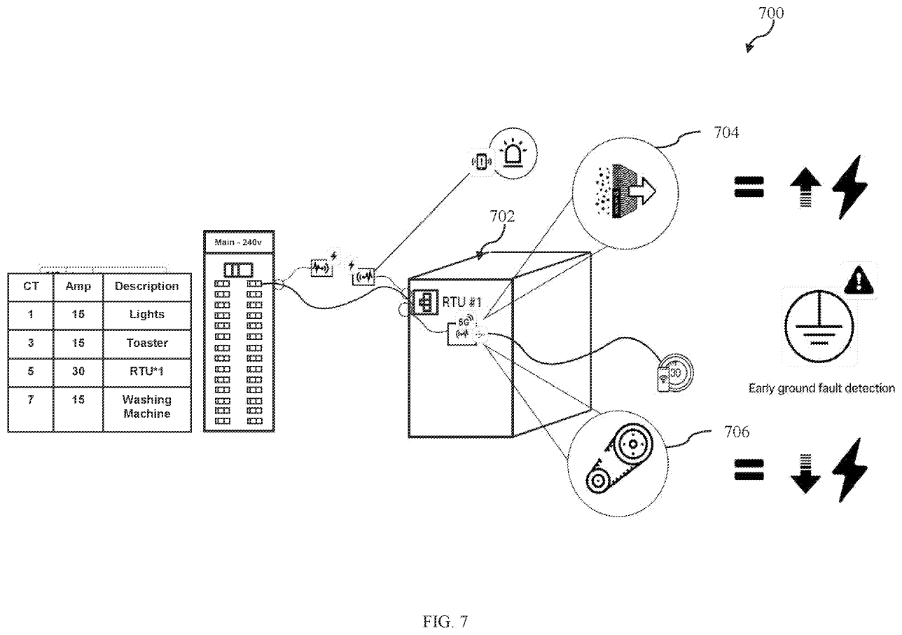

FIG. 7 is an illustration showing an environment that may be monitored by the power monitoring system, according to an exemplary embodiment. With reference to FIG. 7, there is shown an environment 700 that may be monitored by the power monitoring system. In an embodiment, the power monitoring system and/or the IoT device 202 of the present disclosure, may be configured to monitor electricity use, identify anomalies that could signify problems, and suggest possible remedial, or corrective actions. In an example shown in FIG. 7, the power monitoring system may determine an anomaly with a heating, ventilation and cooling (HVAC) system 702 based on an increased amount of power drawn from the line by the HVAC system 702 and detected by the power monitoring system 104. In one exemplary response, the IoT device 202 may suggest that filters 704 be replaced on the HVAC system 702 as the second unit has determined that the HVAC system 702 has been drawing more current than usual. Or in another exemplary response, the IoT device 202 may suggest that a broken fan belt needs to be replaced on the HVAC system 702 as the second unit has determined that the HVAC system 702 has been drawing less current than usual.

In an embodiment, the power monitoring system may implement an execution of multiple artificial intelligence and machine learning algorithms including deep learning algorithms that are executable, in situ, on a processor of the power monitoring system. The power monitoring system of the present disclosure can mimic and control the entire circuit, once each load is mapped to a line thus serving as a digital twin of the mapped circuit.

In an embodiment, the power monitoring system can proactively diagnose issues that are imminent and likely to occur in the foreseeable future using machine learning (ML) and, in response, provide automated, actionable alerts to building managers, for example, electrical workers/technicians. For instance, if a heating element in a hot water tank corrodes, it becomes either increasingly costly on an electricity bill and/or a matter of increasing risk to operate, or compromised safety, before it blows up and needs to be changed, the power monitoring system may detect this anomaly based on the operational characteristics and determine when a replacement is required.

Although in embodiments described earlier herein, it has been disclosed that the first device and the second device comprise a receiver and a transmitter respectively, it is possible that, in alternative embodiments, the first and second devices can be embodied as transceivers that are capable of establishing bi-directional communication with one another as well as the power monitoring system and the IoT device 202 as shown in FIG. 7. This can make identifying certain anomalies easier and quicker. For instance, the IoT device 202 could monitor timestamps when signals were sent to and from these pair of transceivers using which the transceiver, for example, with the second unit could indicate whether or not there has been an early ground fault in the circuit.

In another embodiment, the power monitoring system can also include a diagnostic module to perform diagnosis on impending or future, airflow issues in HVAC systems (e.g., 702). This module leverages the implementation and use of historical trending data for capturing patterns and anomalies over time. By integrating event specific markers, indicators of potential problems are highlighted. As such, the diagnostic module may implement an execution of artificial intelligence and/or machine learning (ML) engines or framework including the algorithms. These AI framework with the machine learning engines may analyze vast datasets, and detect patterns that might elude manual inspection. The diagnostic module may implement the grey box system identification approach, blending known parameters with predictive modelling. This ensures a comprehensive understanding of the system's behavior, even when not all variables are known. As a result, the diagnostic module can pinpoint issues ranging from clogged filters 704 to misaligned or broken belts 706 with remarkable accuracy. Therefore, implementation of embodiments of the power monitoring system may enable enhancing the efficiency of HVAC systems and prolong their lifespan by ensuring timely maintenance.

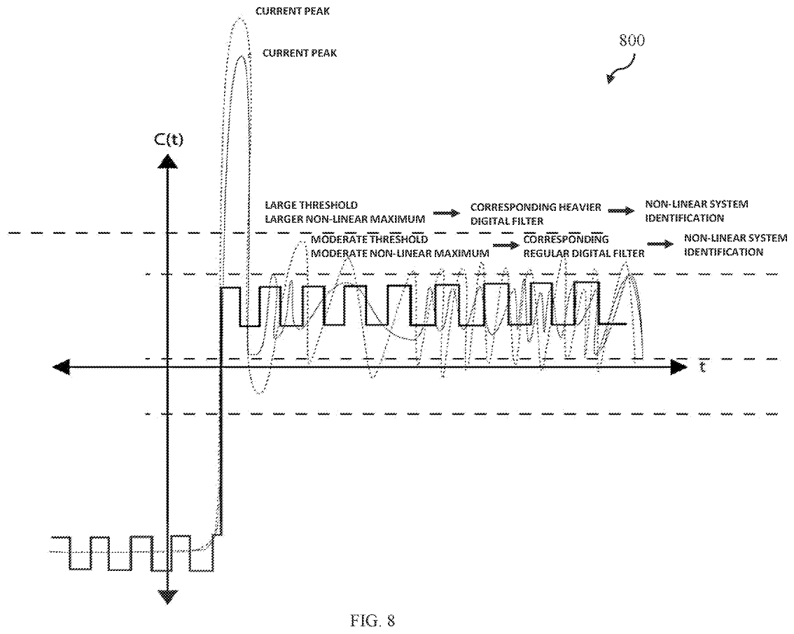

FIG. 8 is an illustration showing a graph that is generated based on an implementation of multiple digital filtering techniques by the power monitoring system, according to an exemplary embodiment. With reference to FIG. 8, there is shown a graph 800 that includes monitoring of multiple electrical loads including steady state conditions and transient inrush current event. In an embodiment, the power monitoring system may implement a mechanism that employs specialized thresholds and incorporates multiple digital filtering techniques, including Infinite Impulse Response (IIR), Finite Impulse Response (FIR), and Fast Fourier Transform (FFT) algorithms. The power monitoring system may implement the above described mechanism to enhance the identification and monitoring of various electrical loads, particularly focusing on both steady-state conditions and transient inrush current events.

In an embodiment, the power monitoring system may implement an advanced mechanism for detecting non-linearities in electrical loads, such as brush DC motors in vacuum cleaners and transformers. Specialized thresholds as shown in Table 3 are employed, which can be dynamically or statistically declared, enabling the power monitoring system to adapt to the specific type and size of the load being monitored.

TABLE 3

| | |
|---|---|
| Adaptive Threshold | The power monitoring system's thresholds |
| | can be adapted in two ways: dynamically and |
| | statically. In the dynamic mode, an algorithm |
| | continuously analyzes the incoming data to |
| | adjust the threshold values in real-time, |
| | enabling immediate responsiveness to |
| | changes in load conditions. In the static |
| | mode, the system uses historical data to set |
| | the threshold values, providing a more stable |
| | but less responsive setup. |
| Critical Feature | A critical feature of power monitoring system |
| | may be configured to note the maximum |
| | value during an inrush current event and |
| | compare it to the value once the system |
| | reaches a steady state. If the maximum value |
| | is twice that of the steady-state value, this |
| | serves as a significant indicator for |
| | determining the type of load that has been |
| | connected. |
| User Interface | The power monitoring system may be |
| and Alerts | configured to cooperatively work with a user |
| | interface module that may provide a user |
| | interface to provide real-time monitoring and |
| | alerts. When a significant inrush current |
| | event is detected, the user is notified through |
| | visual and auditory alerts, allowing for |
| | immediate action if necessary. |
| Advanced Filtering | Upon reaching specialized thresholds, the |
| and Feedback Loop | power monitoring system may activate |
| | advanced digital filtering techniques, |
| | including IIR and FIR filters. These are used |
| | in tandem with FFT algorithms that monitor |
| | specific frequency bands. The combination of |
| | these filtering methods and FFT algorithms |
| | creates a feedback loop. This feedback loop |
| | dynamically adjusts both the threshold values |
| | and the characteristics of notch or bandstop |
| | filters used for monitoring, thereby fine- |
| | tuning the system's settings for optimal |
| | performance. |

In an embodiment, the power monitoring system implements an execution of an advanced layer of monitoring of the electrical loads. The power monitoring system 14 implements specialized thresholds, advanced digital filtering techniques, and FFT algorithms to offer a nuanced and precise analysis. The above described mechanism may enhance the power monitoring system ability to identify various types of loads and improves the accuracy of its analyses of both steady-state conditions and transient inrush current events.

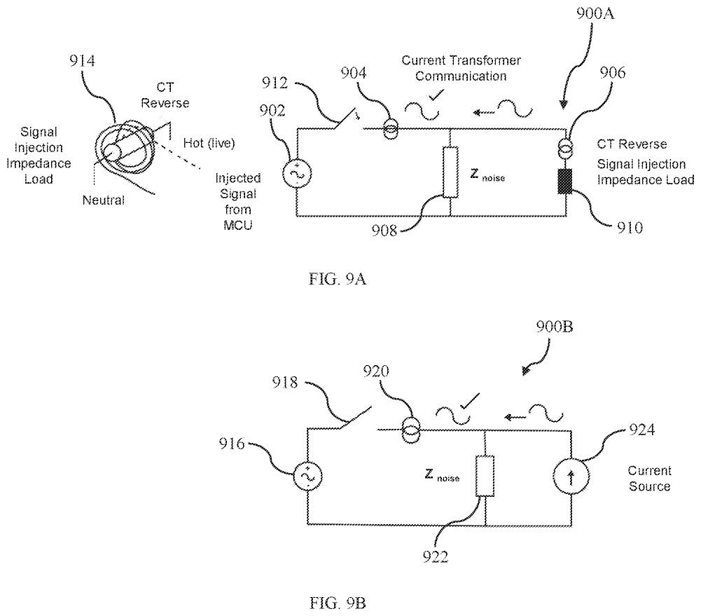

FIG. 9A and FIG. 9B are illustrations showing an implementation of the power monitoring system automating the identification of wall outlets connected to specific circuit breakers, according to an exemplary embodiment. With reference to FIG. 9A and FIG. 9B, there is shown an implementation 900A and 900B of a reverse-operated CT 104 in the power monitoring system may implement a mechanism that automates the identification of wall outlets connected to specific circuit breakers. A unique current signal is generated by a microcontroller and injected into the circuit via a reverse-operated CT in the power monitoring system wrapped around a coupling resistor at the wall outlet. This signal is detected by another CT 104 in the power monitoring system near the circuit breaker, and a second microcontroller processes it for identification. The other components of FIGS. 9A and 9B include power source 902, and resistors (e.g., 908, 910).

In an embodiment, the power monitoring system may implement electrical system management. For example, it may include identifying which wall outlet is connected to a specific circuit breaker (e.g., 912) is a critical task. The reverse-operated CT method in the power monitoring system implements a mechanism to automate the detection of which wall outlet is connected to the specific circuit breaker (e.g., 912). At the wall outlet, a coupling resistor (e.g., 910) is placed between the hot and neutral wires to facilitate the injection of a unique current signal. This coupling resistor (e.g., 910) is chosen to enable effective signal injection while minimizing power dissipation and ensuring safety. A microcontroller connected to a reverse-operated CT generates this unique current signal. The CT in the power monitoring system, wrapped around the coupling resistor, injects the signal into the electrical circuit. As the signal propagates through the circuit, it joins the existing load current but retains its unique characteristics, making it distinguishable from other currents in the system.

In an embodiment, at the circuit breaker, another CT 104 is strategically placed to detect currents flowing through the circuit. This CT picks up the injected signal along with the existing load current. A second microcontroller connected to this CT 104 is responsible for processing the received signal. By implementing signal processing techniques, it isolates the unique current signal from the existing load current. Once isolated, the unique signal serves as an identifier, mapping the wall outlet to its corresponding circuit breaker.

In an embodiment, the above described mechanism enables real-time, automated identification of wall outlets, thereby enhancing system management and safety. It eliminates manual tracing of circuits, reduces the risk of errors, and improves operational efficiency. By leveraging the capabilities of reverse-operated and standard CTs, along with microcontrollers for signal generation and processing, this approach provides a reliable and efficient solution for electrical system management.

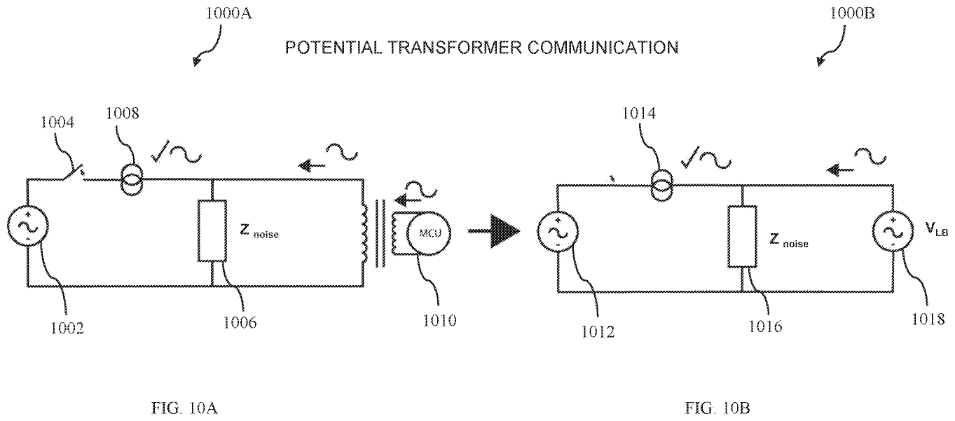

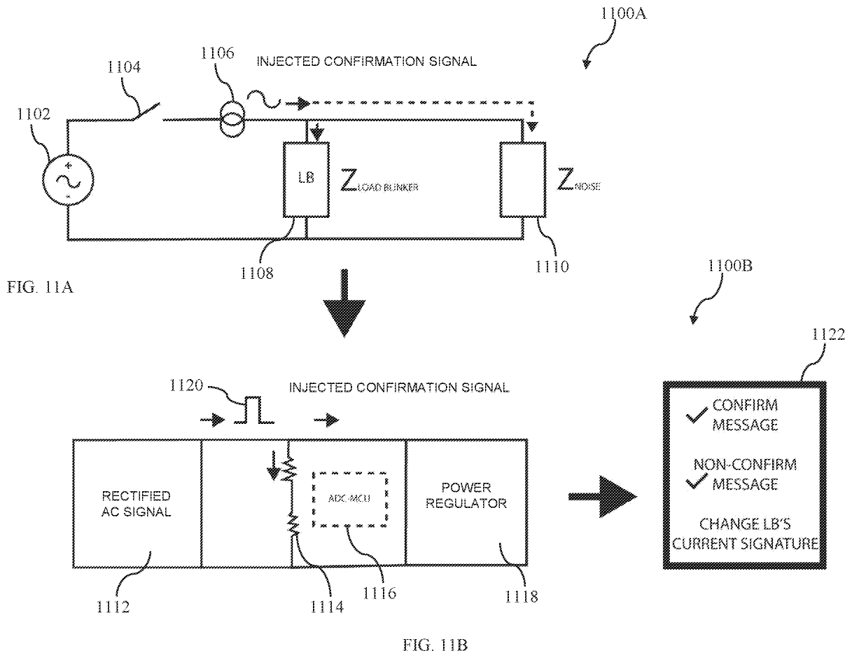

FIG. 10A and FIG. 10B are illustrations showing an implementation of the power monitoring system automating the identification of wall outlets connected to specific circuit breakers, according to an exemplary embodiment. With reference to FIG. 10A and FIG. 10B, there are respectively shown illustrations 1000A and 1000B that implement a mechanism of automating the identification of wall outlets connected to specific circuit breakers using potential transformer (PT) method. In an embodiment, the power monitoring system may implement the PT (e.g., 1010) method or mechanism to automate the identification of wall outlets connected to specific circuit breakers (e.g., 1004). A unique voltage signal is generated by a microcontroller and directly injected into the circuit via a PT connected between the hot and neutral wires at the wall outlet. This signal is detected by a CT (e.g., 1008) near the circuit breaker (e.g., 1004), and a second microcontroller processes the signal for identification. At the wall outlet, a PT (e.g., 1010) is directly connected between the hot and neutral wires. This direct connection allows for the efficient injection of a unique voltage signal into the electrical circuit.

In an embodiment, a microcontroller connected to the secondary winding of the PT generates this unique voltage signal. The PT (e.g., 1010) then injects the signal into the primary electrical circuit. The injected signal induces a current in the circuit, which is proportional to the impedance (e.g., 1006) of the circuit and the voltage signal. This induced current flows through the circuit and retains its unique characteristics, making it distinguishable from the existing load current. At the circuit breaker panel, a CT is installed to detect the currents flowing through the circuit. This CT captures both the existing load current and the induced current from the PT. A second microcontroller, connected to this CT, is tasked with processing the received signals. Employing signal processing techniques, it isolates the unique induced current from the existing load current. Once isolated, this unique signal serves as an identifier, effectively mapping the wall outlet to its corresponding circuit breaker. Other components of FIGS. 10A and 10B are voltage source 1002, 1012, 1018, impedance matching resistor 1016, 1008 and 1014.

In an embodiment, by using a PT for signal injection and a CT for signal detection, this mechanism provides a robust and automated way to identify and map wall outlets to specific circuit breakers. The above described mechanism eliminates the need for manual circuit tracing, enhances system safety, and improves operational efficiency.

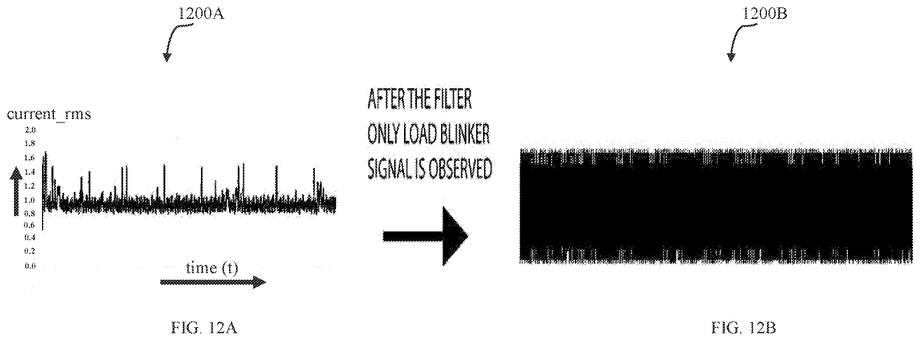

FIG. 11A and FIG. 11B are illustrations of a dual function current transformer implemented by the power monitoring system, according to an exemplary embodiment. With reference to FIG. 11A and FIG. 11B, there are respectively shown illustrations 1100A and 1100B of dual function current transformer. In an embodiment, the dual-function current transformer (CT) system enables two-way communication between wall outlets and circuit breakers. In this mechanism, the implementation may include both the CT at the wall outlet and the CT at the circuit breaker panel act as transceivers. The CT at the circuit breaker can inject either a “confirmation” or a “non-read” signal back to the wall outlet, depending on whether it successfully reads the incoming signal. The device at the wall outlet interprets these signals to either confirm successful transmission or to modify and resend the signal.

In an embodiment, two-way communication between wall outlets and circuit breakers is essential for real-time identification and dynamic adjustments. The multi-method transceiver system provides this capability by employing both the device at the wall outlet and the CT at the circuit breaker panel as transceivers. Initially, a microcontroller at the wall outlet generates a unique signal for injection into the electrical circuit. This signal can be injected using one of three mechanisms, for example, a reverse-operated CT that acts as a current source, a PT that injects a unique voltage signal directly between the hot and neutral wires, or by merely switching an impedance load ON and OFF to create a unique current pattern in the circuit.

Regardless of the mechanism used, the signal travels through the electrical circuit and is detected by a CT (e.g., 1106) located near the circuit breaker (e.g., 1104). A second microcontroller processes this received signal to determine its readability. Based on this assessment, the CT at the circuit breaker panel injects a corresponding signal back into the circuit. If the incoming signal is readable, a “confirmation” message is sent. If not, a “non-read” message is injected (e.g., 1122). These injected signals induce a slight voltage change at the power supply of the microcontroller at the wall outlet, serving as a feedback mechanism.

For a “confirmation” message, the slight voltage increase at the microcontroller's power supply confirms that the initial signal was successfully received and identified. For a “non-read” message, the device at the wall outlet interprets this as a cue to modify the transmitted signal and initiate the process again.

In an embodiment, by enabling the device at the wall outlet to act as a transmitter using one of three methods reverse-operated CT, PT, or impedance load (e.g., 1108, 1110, 1112) switching and the CT at the circuit breaker panel to act as a transceiver, this system provides a robust, real-time communication mechanism. It not only automates the identification of wall outlets but also allows for dynamic adjustments to the transmitted signals, enhancing the system's reliability and efficiency.

FIG. 12A and FIG. 12B are illustrations showing an implementation of analog and digital filtering techniques implemented by the power monitoring system, according to an exemplary embodiment. With reference to FIG. 12A and FIG. 12B, there is shown an implementation of analog and digital filtering techniques by the power monitoring system. For example, 1200A of FIG. 12A shows signals before filtering and 1200B of FIG. 12B shows the load blinker signal that is observed after implementation of the digital and analog filtering techniques. In an embodiment, the power monitoring system 104 implements three distinct filtering techniques-Analog Filtering, FIR Digital Filtering, and IIR Digital Filtering—to isolate a specific high-frequency signal used for circuit breaker mapping. These methods prepare the signal for subsequent FFT analysis, ensuring it is readable and identifiable at the output, despite the presence of multiple injected signals from noise loads. In an embodiment, in the task of detecting a high-frequency signal for the purpose of mapping circuit breakers to wall outlets, the power monitoring system 104 faces the challenge of isolating the desired signal from a multitude of other injected signals. These extraneous signals often originate from noise loads, such as devices plugged into wall outlets or lines running in parallel to the transmitting device. To address this, the power monitoring system 104 utilizes one of three filtering methods before analyzing the signal using FFT.

In an embodiment, the analog filters are implemented using a combination of electronic components like resistors, capacitors, and inductors. These filters are particularly useful for real-time applications due to their low latency. They are designed to isolate the high-frequency signal of interest, making it easier to identify during FFT analysis. The FIR filters operate in the digital domain and are typically executed via a microcontroller. These filters are designed to have a linear phase response, which is beneficial for preserving the integrity of the signal shape. The FIR filter effectively isolates the high-frequency signal, preparing it for FFT analysis and making it distinguishable from other noise loads in the system.

In an embodiment, the IIR filters are another digital filtering option, offering computational efficiency with fewer coefficients. This makes them a suitable choice for systems with resource-constrained microcontrollers. Like the FIR filter, the IIR filter isolates the high-frequency signal, making it easier to identify during FFT analysis. After the signal has been filtered using one of the above described filtering techniques, it is subjected to FFT for frequency domain analysis. The FFT output allows for the isolated high-frequency signal to be easily identified and read, even in the presence of multiple injected signals from noise loads. This enables accurate mapping of wall outlets to specific circuit breakers, providing a robust and reliable system for electrical management.

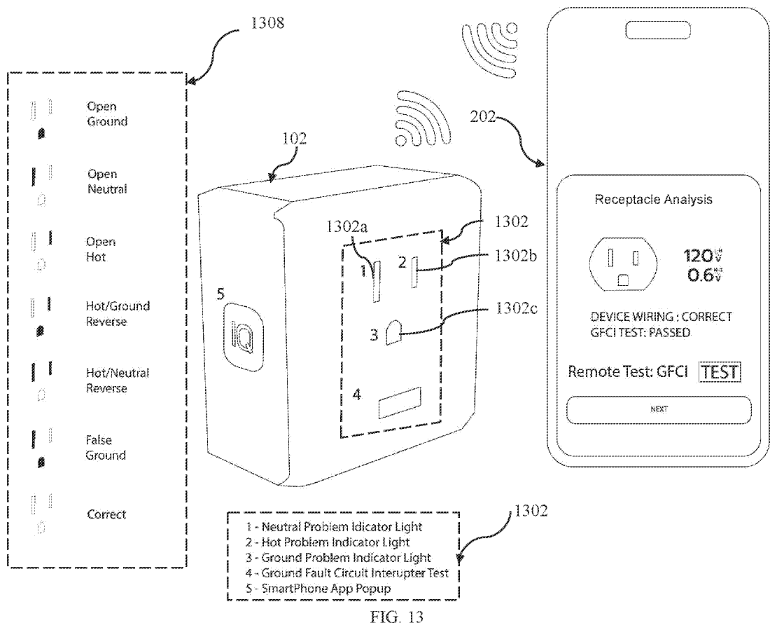

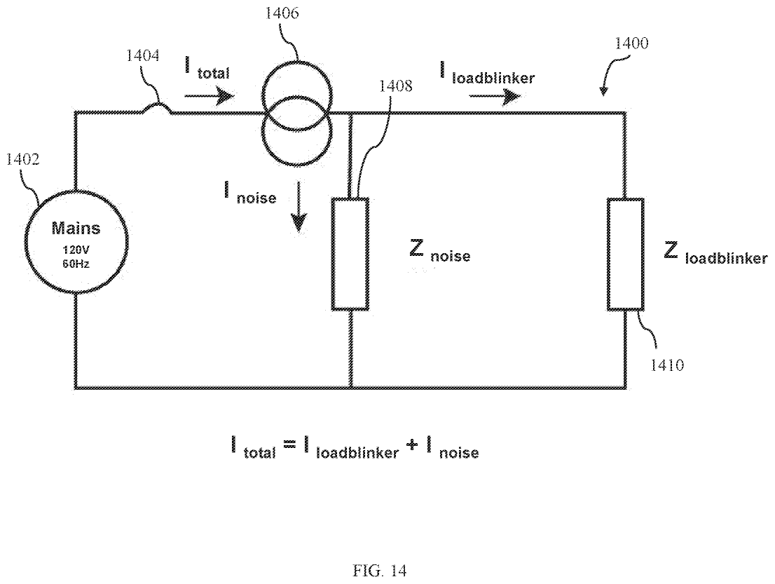

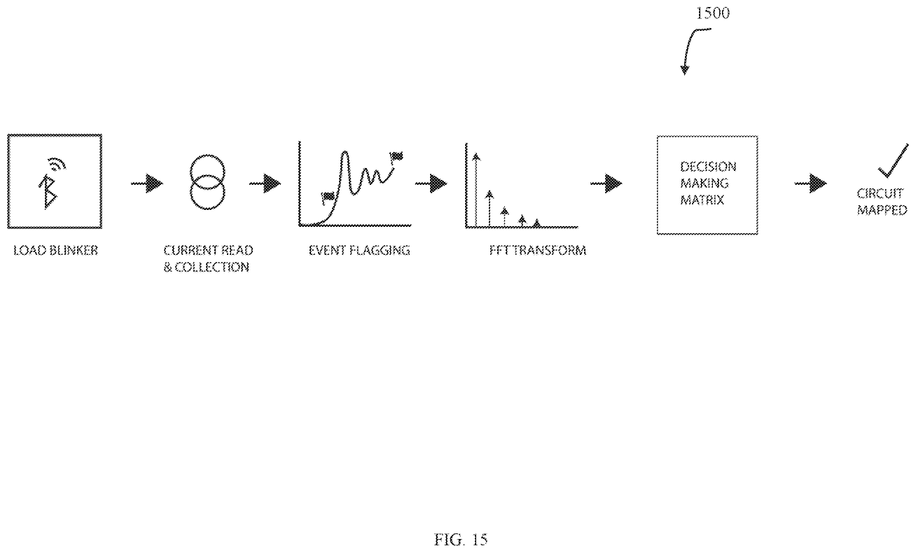

FIG. 13 is an illustration showing the load blinker with an intuitive plug outlet tester, according to an exemplary embodiment. With reference to FIG. 13, there is shown the load blinker 102 that may be provided with an intuitive plug outlet tester 1302 that can perform wireless reporting and advanced fault detection. In an embodiment, the plug outlet tester 1302 of the load blinker 102 may be designed such that it would be compatible for releasable engagement with standardized designs of outlets (wall sockets) while also being configured with the ability to detect improper wiring of the outlet. Preferably, the plug outlet tester 1302 of the load blinker 102 displays these results through three indicator lights 1304a-1304c located on a front of the load blinker 102 but they will be positioned to be in the likeness of the outlet shape itself. In this manner, the plug outlet tester 1302 and the load blinker 102 can be used and read easily without the need for sticker legends or other interpretive notes that are typically used on average plug testers owing to their poor user interface (UX) design. The load blinker 102 may wirelessly transmit results of the test to the IoT device 202 and/or the power monitoring system 104 so that the IoT device 202 and/or the power monitoring system is able to use this for faulty wiring detection and electrical safety report generation. Error states 1308 displayed dynamically by the three indicator lights 1304a-1304c of the load blinker 102 may include, for example, Open Ground, Open Neutral, Open Hot, Hot/Ground Reverse, Hot/Neutral Reverse, False Ground and Correct Wiring that occurs when Neutral is tied to Ground. These error states 1308 consist not only of regular fault states but also extend to include indications of false ground detections in which one of a bootleg ground or a bootleg ground with hot/neutral, ground reverse may be occurring.

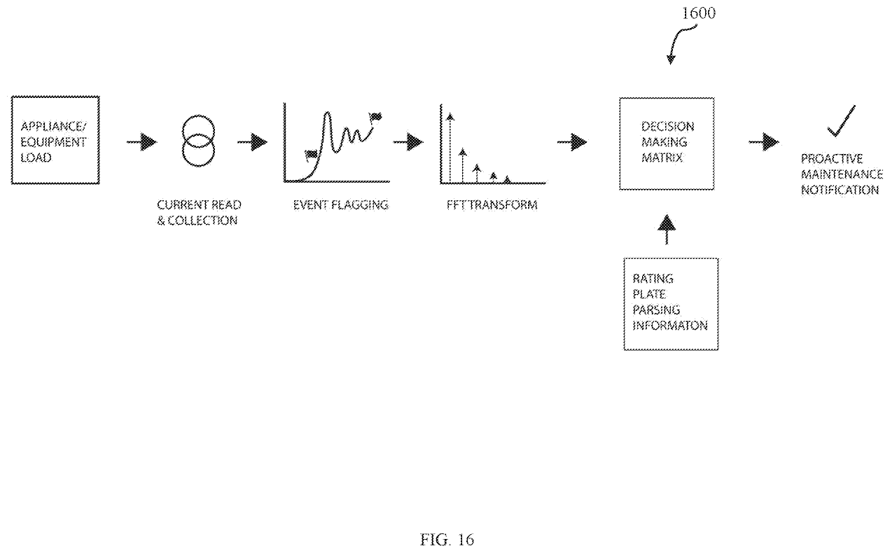

FIG. 14 shows an illustration of live line detection circuit, in accordance with an exemplary embodiment. With reference to FIG. 14, there is shown a live line detection circuit as the Norton Equivalent circuit with the current transformer measuring the current being generated by load blinker and any impedance load already on the circuit, that is all connected to a circuit breaker. Current being drawn into the load blinker can be added with the current of the noise loads. This is known as Kirchhoff Current Law where I_{Total}=I_{Noise}+I_{LoadBlinker}. Where the current monitoring device, shown as the circle 104, monitors for I_{Total}. This system must be able to monitor for I_{LoadBlinker} while being able to ignore whatever I_{Noise} may be.

FIG. 15 is an illustration showing a high level diagram of how a live line detector detects load blinker on the line when noise is present, according to an exemplary embodiment. With reference to FIG. 15, there is shown a high level diagram of how a live line detector detects load blinker on the line when noise is present. In an embodiment, the load blinker 102 transmits data, which is then picked up by the current sensor (CT or PT). Attributes such as voltage, current, phase, and power are stored from the captured data. This data is subsequently processed through algorithms specifically designed to filter out events from noise within the power line. This procedure aids in distinguishing areas where the load blinker's 102 data can be interpreted without difficulty, as well as areas where such interpretation may be challenging. Following this, the data is grouped into bins and then converted into the frequency domain. At this point, a decision-making matrix comes into play. It evaluates the processed information to ascertain whether the Load Blinker is actively transmitting, thus helping in power source identification.

FIG. 16 is an illustration showing a high level diagram of the power monitoring system generating maintenance logs, according to an exemplary embodiment. In an embodiment the power monitoring system may be configured to generate maintenance logs. For instance, the live line detector can create proactive maintenance logs derived from data readings. Noteworthy events are first identified and flagged. Subsequent analysis of these flagged incidents, in combination with parsing rating plate data, helps to determine whether equipment is functioning as expected post signal analysis.

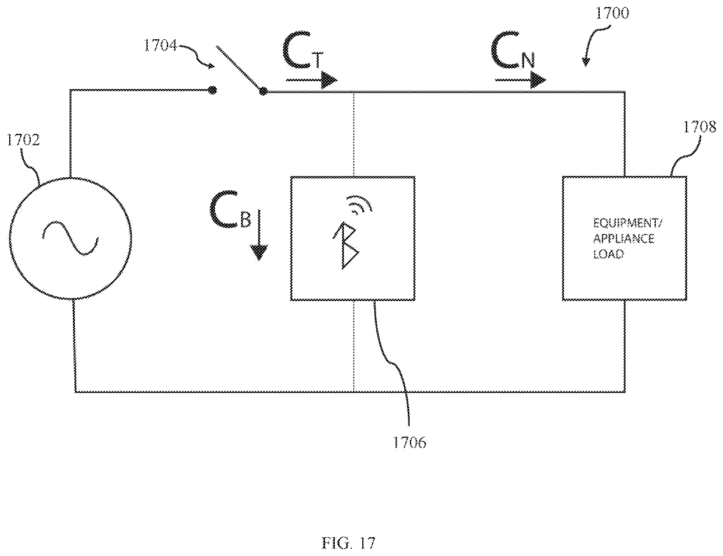

FIG. 17 is an illustration of a circuit that implements Kirchoff's Current Law, according to an exemplary embodiment. With reference to FIG. 17, there is shown a circuit diagram 1700 that implements the principle of Kirchoff's Current Law (KCL). The circuit 1700 shown in FIG. 17 includes voltage source 1702, circuit breaker 1704, load blinker 1706 and equipment/appliance load/impedance 1708. In an embodiment, KCL states that the sum of currents entering a node (or junction) in a circuit must equal the sum of currents leaving it. When applied to a circuit breaker connected to a wall outlet, any device plugged into that outlet would introduce its current signature into the circuit, including the load blinker 1706. If multiple devices are connected in parallel to this circuit, their respective current signatures combine at the circuit breaker 1704. Therefore, a current transformer connected at the circuit breaker 1704 would measure the sum of the signal from the transmitting device and the currents from all other devices connected in parallel.

In a practical scenario, a transmitter connected to a wall outlet introduces its unique current signature into the circuit that requires frequent detection for proper system operation and monitoring. However, the situation gets complicated when additional devices are connected in parallel to the same circuit. Each of these devices injects its own distinctive current signature into the circuit, leading to a mix of several currents flowing through the system. Certain transient events, such as inrush currents associated with the activation of electrical devices, can produce complex step responses. These responses, superimposed on the original signal of the transmitter, can create an extremely convoluted electrical scenario.

In an embodiment, the presence of these multiple devices, each contributing its own current and corresponding disturbances, can significantly hamper the clear and regular detection of the transmitter signal. The current transformer placed at the circuit breaker, despite its role in measuring the total current, faces challenges in distinguishing the specific signature of the transmitter amidst this amalgamation of various signals and the disruptive influences of transient events.

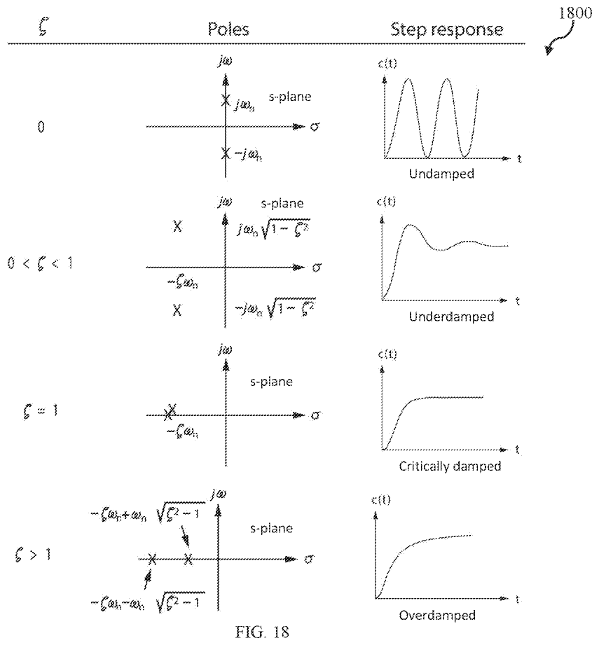

FIG. 18 is an illustration showing main responses for event flagging, according to an exemplary embodiment. With reference to FIG. 18, there is shown responses 1800 for event flagging. In an embodiment, the event flagging may include, for example, four main responses that are deterministic based dampening ratio ζ. These may include an oscillatory response, an underdamped response, a critically damped response and an overdamped response. For event flagging there are four main responses undamped which is oscillatory and ζ is zero, underdamped which is less stable where ζ is towards ζ, critically damped which is most stable and when ζ is 1. Then underdamped which is less stable, but it is when ζ is greater than 1.

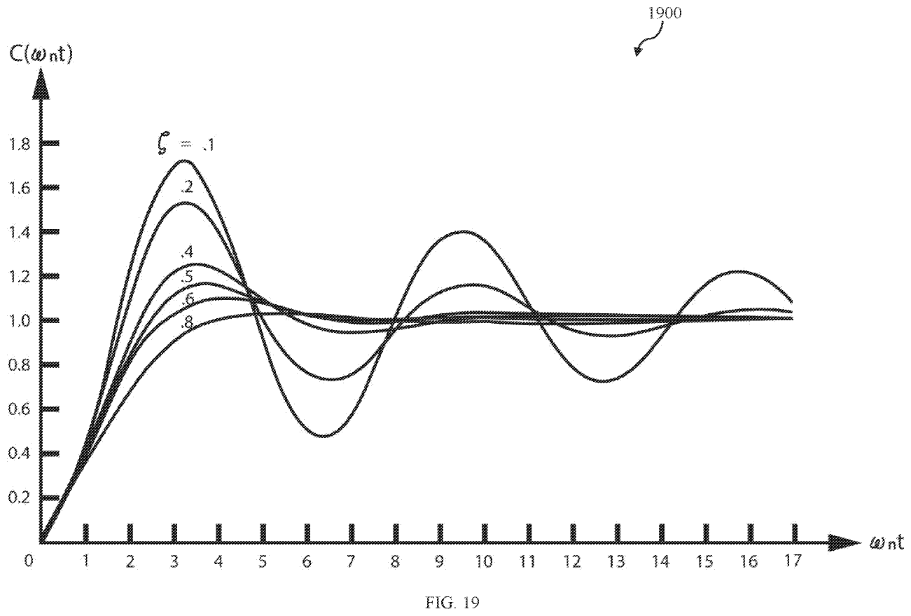

FIG. 19 is an illustration showing inrush current events, according to an exemplary embodiment. With reference to FIG. 19, there is shown a graph 1900 that includes the response to inrush current event. ζ affects the inrush current event such that the peak current, the subsequent dampened oscillations are increased as ζ approaches 0. In an under-damped system (0<ζ<1), the response to a change is initially rapid, but it then tends to oscillate around the final value before eventually stabilizing. As ζ approaches 0, these oscillations become more pronounced and sustained. This effect of the damping ratio on inrush current is crucial as it impacts the system's stability and responsiveness, which could further have significant implications for the operation and life span of the overall system or equipment.

FIG. 20 is an illustration showing undamped system's inherent oscillation rate, according to an exemplary embodiment. With reference to FIG. 20, there is shown a graph 2000 that shows inherent oscillation rate. In an embodiment, the natural frequency ωₙ in control theory refers to an undamped system's inherent oscillation rate when no external inputs are applied. It significantly influences the system's response speed and transient behavior, such as overshoot and settling time. The natural frequency represented as ωₙ, in control theory signifies the inherent oscillation rate of a system in the absence of external inputs or damping. This frequency is determined by intrinsic properties of the system, such as inductance and capacitance in electrical systems. Whether under conditions of free or forced vibration, the natural frequency profoundly impacts the system's response. Specifically, it dictates transient response characteristics including speed of response, degree of overshoot, and settling time. In a step response scenario, the natural frequency primarily governs the rate of oscillations and the system's settling time.

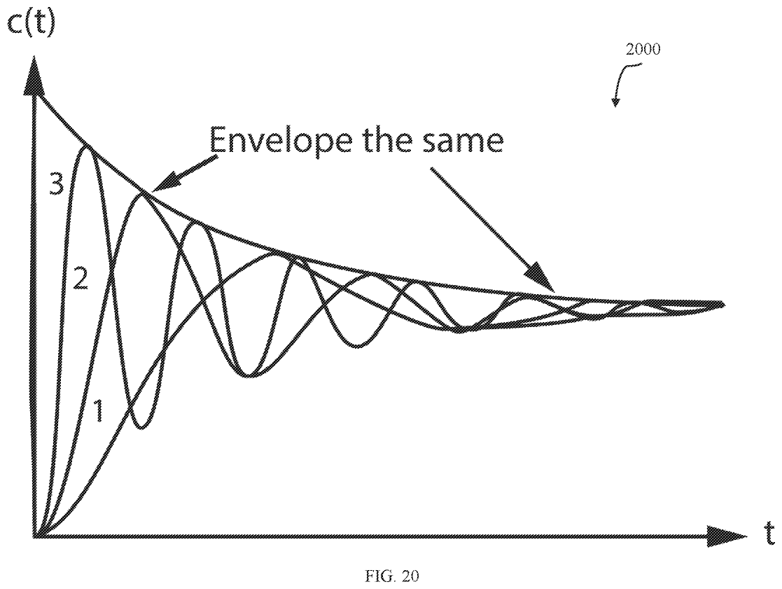

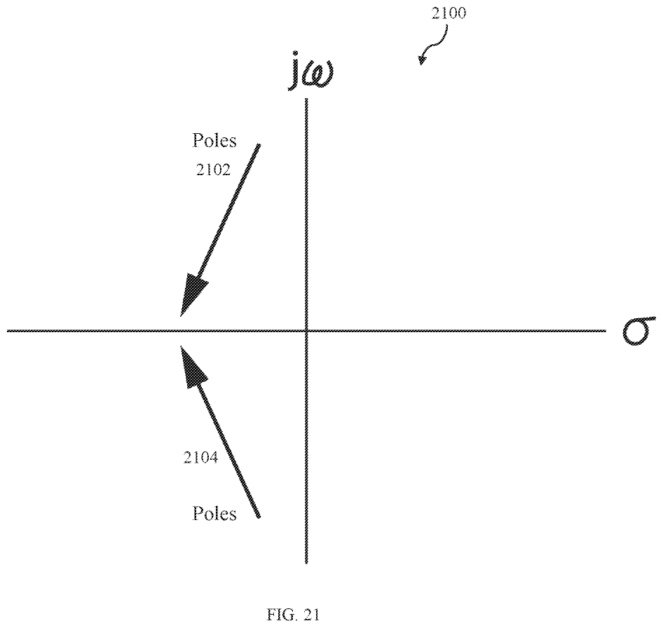

FIG. 21 is an illustration showing movement of poles on a s-plane, according to an exemplary embodiment. With reference to FIG. 20, there is shown movement of poles 2100 on the s-plane. In an embodiment, the movement of poles (e.g., 2102 and 2104) on the s-plane, as depicted by the root locus, can directly impact system stability. Moving poles towards the real axis (away from the imaginary axis) in the left half-plane typically improves system stability, with the location of the poles directly affecting the system's natural frequency (ωₙ) and damping ratio (ζ). The more it exhibits this behave the easier the system is to read.

In an embodiment, the poles of a system in the s-plane represent the system's natural frequencies. Their locations directly impact both the damping ratio (ζ) and the natural frequency (ωₙ). The root locus provides a graphical representation of the possible locations of poles as a system parameter varies, often the system gain. When poles move closer to the real axis and away from the imaginary axis in the left half-plane, this indicates a decrease in ωₙ and an increase in ζ. This shift towards more real values corresponds to a more overdamped system with slower response times but less oscillatory behavior, hence improved stability. Conversely, poles moving away from the real axis towards the imaginary axis signal an increase in ωₙ and a decrease in ζ, pointing towards a less damped or potentially underdamped system. This system would respond more quickly to changes but might exhibit significant overshoot and longer settling times. Therefore, the movement of poles and its effects on the system's natural frequency and damping ratio is a crucial consideration in event flagging.

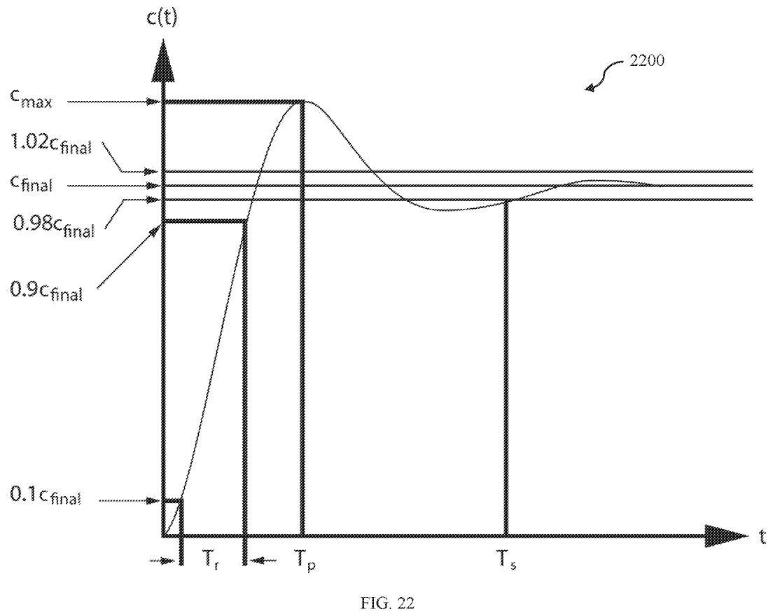

FIG. 22 is an illustration showing current during an inrush current event, according to an exemplary embodiment. With reference to FIG. 22, there is shown the current during an inrush current event. In an embodiment, observing the current during an inrush current event enables to determine key parameters such as the start time and amplitude, the time and amplitude of the peak current, and the settling time and final current value. The initial surge's amplitude represents the start of the inrush current, while the maximum current and its occurrence time reflect the peak inrush event. The difference between these values and the final steady-state current, observed at the settling time, provides the percentage overshoot value (% OS).

In an embodiment, an inrush current event, a sudden change in current is observed. This begins at the start time, where the initial jump in current represents the beginning of the inrush. The amplitude of this initial surge is critical as it gives the initial change in current. As the event progresses, the current reaches its maximum value, which is the peak of the inrush current. The time at which this occurs is equally important as it provides information about the system's speed of response. The amplitude of this peak current represents the maximum deviation from the steady-state current. After the peak, the current starts to settle back towards its steady-state value. The time it takes to reach this steady state is known as the settling time. The final current value at this settling time represents the steady-state current after the inrush event. By comparing the peak current amplitude with the steady-state current, we can calculate the percentage overshoot (% OS). This value represents the extent to which the peak current exceeds the steady-state current, providing valuable insight into the system's response characteristics and potential for instability.

FIG. 23 is an illustration showing overshoot percent computed using computational method, according to an embodiment. With reference to FIG. 23, there is shown a graph 2300 showing overshoot percent computed using computational method. In an embodiment, with the known overshoot percent known from the observed event flagging event, we must solve for ζ by using a computational method. When the percentage overshoot (% OS) of an event is known through flagged observations, it becomes necessary to calculate the damping ratio, ζ, in order to further understand the system's dynamics. However, this task often presents computational challenges as the equation involving % OS and ζ is usually nonlinear and cannot be factored easily to directly solve for ζ.

In an embodiment, several numerical methods can be employed to tackle this issue. One of these is the bisection method, a simple yet effective algorithm based on the intermediate value theorem for continuous functions. It works by iteratively dividing an interval into two halves and selecting the subinterval where the function changes sign. Another popular method is the Newton-Raphson method, which uses tangents to the function to find its roots. While this method can be faster than the bisection method, it requires the function to be differentiable and doesn't guarantee global convergence. Alternatively, Brent's method can be employed, which combines the bisection method, the secant method, and inverse quadratic interpolation. It has the robustness of the bisection method and the speed of the Newton-Raphson and secant methods.

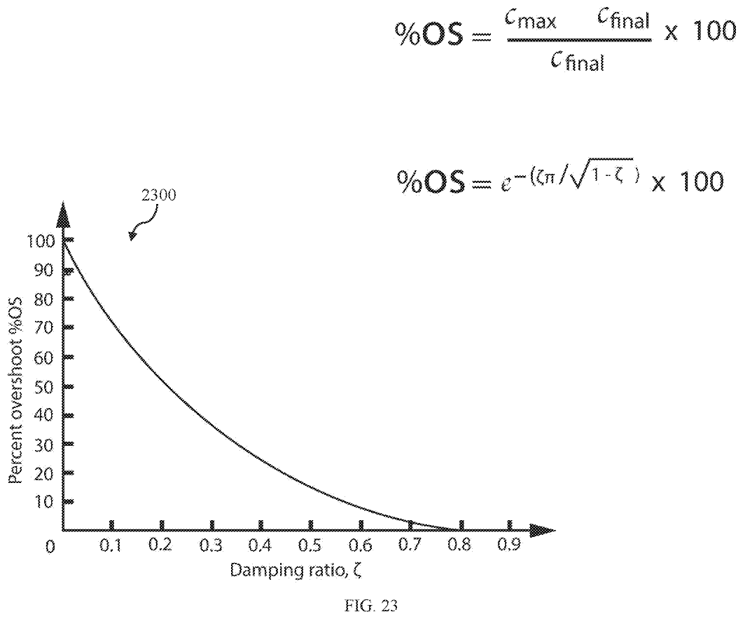

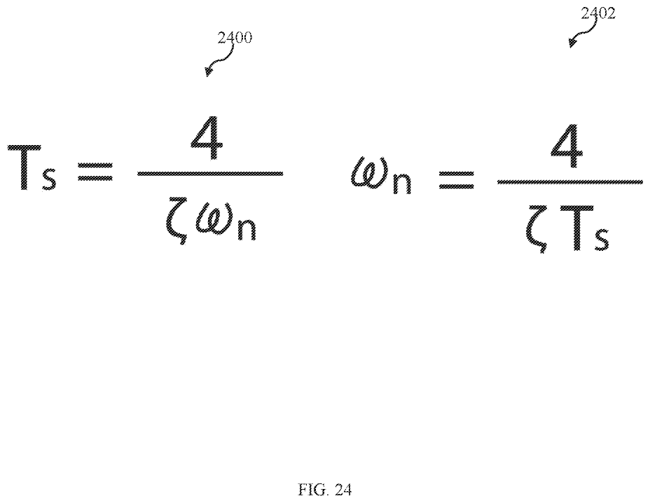

FIG. 24 is an illustration showing computations of natural frequency, according to an exemplary embodiment. With reference to FIG. 24, there is shown equations for computations 2400 and 2402. In an embodiment, since damping ratio (ζ) and settling time (Ts) are known natural frequency ωₙ is easily calculable. The damping ratio (ζ) and the natural frequency (ωₙ) are two fundamental parameters of a control system. They essentially characterize the dynamics of the power monitoring system 104, providing crucial insight into its behavior and performance. The damping ratio (ζ) is a measure that indicates how oscillations in a system decay after a disturbance. A system with a high damping ratio (ζ) tends to return to steady state without oscillations, while a system with a low damping ratio (ζ) exhibits oscillations that decay over time. Therefore, damping ratio (ζ) provides information about the system's stability and how it reacts to changes or disturbances. The natural frequency (ωₙ) on the other hand, indicates how fast the system can oscillate in the absence of any damping or external forces. It defines the speed of the system's response, influencing parameters such as rise time, settling time, and peak time. Thus, natural frequency (ωₙ) provides information about the system's agility or speed in responding to changes. When damping ratio (ζ) and natural frequency (ωₙ) are known, they provide a fundamental understanding of the system's behavior. This understanding forms the basis for system identification, which is the process of developing a mathematical model of a dynamic system based on observed data. These two parameters damping ratio (ζ) and natural frequency (ωₙ) can also guide the process of tuning or designing controllers to achieve desired system performance.

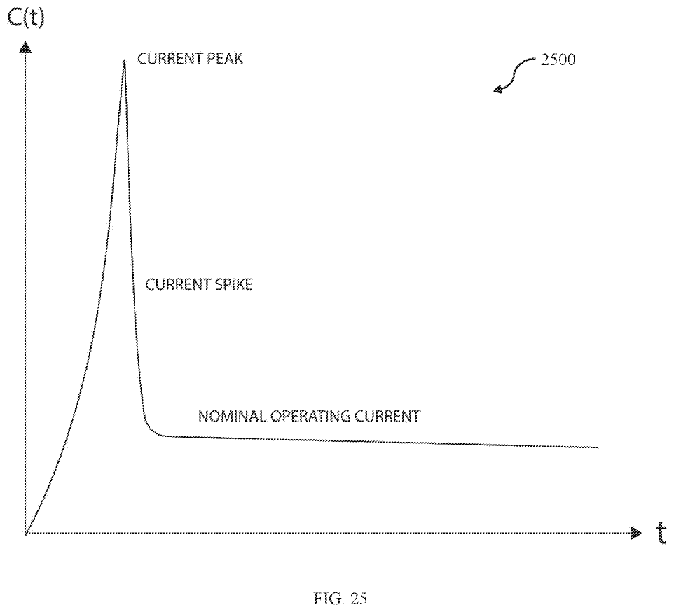

FIG. 25 is an illustration showing a graphical representation of the inrush current phenomenon, according to an exemplary embodiment. With reference to FIG. 25, there is shown a graphical representation 2500 showing the inrush current phenomenon in non-linear systems such as transformers, DC brushed motors, and capacitive loads. The graph 2500 illustrates current RMS as a function of time. The curve shows the inrush current rising sharply upon startup and then gradually falling to a steady-state level.

In an embodiment, the Y-axis represents current RMS in Amperes, and the X-axis represents time in milliseconds. The graph has markers indicating critical points like the initial spike, peak current, and steady-state current. Monitoring inrush current behavior is essential for identifying noise loads on the line in parallel to a load blinker, especially when the natural frequency and damping ratio cannot be determined due to the non-linear nature of these loads. Upon the initiation of power to the device, an immediate and sharp rise in current is observed, herein referred to as the “Initial Spike.” This initial spike is particularly evident in devices like transformers and DC brushed motors, where the current can escalate to several times the nominal operating current within a matter of milliseconds. Following the initial spike, the current ascends to its maximum value, herein identified as the “Peak Current.” Subsequent to reaching the peak current, the system experiences a gradual decay in current as it transitions towards its normal operating condition. Ultimately, the current stabilizes at a constant value, which is the device's nominal operating current. The drawing aims to furnish a comprehensive yet lucid depiction of the inrush current phenomenon in non-linear systems, serving as an instrumental foundation for comprehending the transient behaviors exhibited by such systems upon startup.

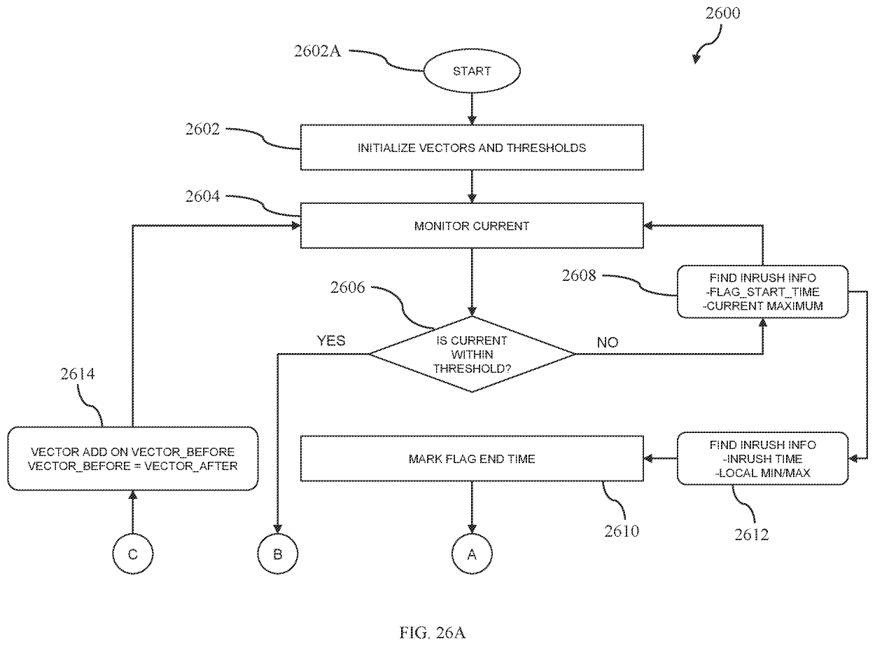

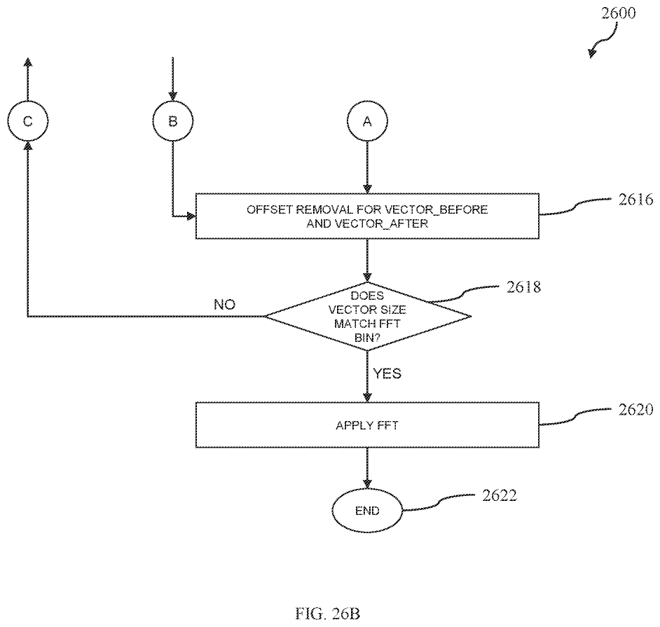

FIG. 26A and FIG. 26B is an illustration showing a flow diagram of operational logic of computer executable code implemented by the power monitoring system, according to an exemplary embodiment. In an embodiment, for the power monitoring system equipped with a blinking load device that induces an oscillation in current, the system implements a logic that is in the form of instructions or code to detect steady-state conditions based on a predefined threshold. The code utilizes vectors before and after the steady-state to normalize offsets caused by inrush current events. These vectors feed into an FFT bin for frequency analysis, ensuring that the oscillating element is represented as an imperfect square wave. In an embodiment, the load blinker is configured to produce a blinking load thereby creating an oscillation in the current of the circuit. This characteristic of the load blinker is particularly beneficial for the nuanced study of transient behaviors in electrical systems.

Referring to FIGS. 26A and 26B, the flowchart 2600 outlines an operational logic of a computer executable code that is integral to the system disclosed herein. This code can help the power monitoring system to identify when the system has reached a steady-state condition. Specifically, as shown, steady-state is flagged when the monitored current RMS aligns with a predefined threshold. The code employs a unique approach involving three vectors: one dedicated to the steady-state, another for the period preceding the steady-state, referred to as “vector_before,” and a third for the period following the steady-state, known as “vector_after.” These vectors serve a dual purpose. First, they normalize the offsets that are introduced when the system reaches a new steady-state due to inrush current events. This normalization ensures that the main vector, which represents the oscillating element, manifests as an imperfect square wave. Secondly, these vectors are instrumental in the Fast Fourier Transform (FFT) analysis. Should the FFT bin reach its capacity, the code is designed to incorporate the inrush current events from “vector_before” and “vector_after” into the main FFT vector, which then feeds into the FFT bin. This approach ensures that the FFT analysis is both comprehensive and accurate. The primary objective of this system is to flag inrush current events for subsequent analysis.

In an embodiment, by focusing the FFT bin exclusively on steady-state readings, the system eliminates the risk of skewing the analysis with transient behaviors, thereby offering a more accurate representation of the electrical system's behavior. The code employs conditional statements that are triggered when the monitored current RMS falls outside and then inside a predefined threshold. Specifically, the code marks the time when the threshold condition is not met as flag_start_time and again when it is met as flag_end_time. The FFT logic is only activated when the sizes of vector_corrected, vector_before, and vector_after match the FFT bin size, ensuring that all offsets are accounted for.

Referring to FIG. 26A and FIG. 26B, the power monitoring system may start monitoring at step 2602A. Further, the vectors and thresholds are initialized at step 2602. The current is monitored at step 2604. The monitored current is checked if within threshold at step 2606. If the monitored current is within threshold (YES), the process 2600 continues to step 2616. If the monitored current is not within the threshold (NO), the process 2600 continues to step 2608. From step 2608, the process 2608 either continues to step 2604 or to step 2612. At step 2618, a check is made if the vector size matches the FFT BIN. If false (NO), then the process 2600 continues to step 2614. If true (YES), the FFT is applied at step 2620 and process 2600 ends at step 2622.

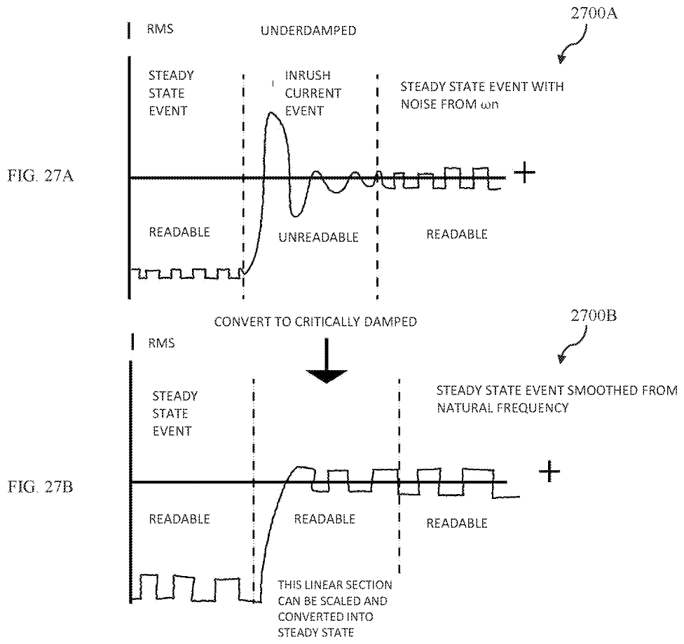

FIG. 27A and FIG. 27B are illustrations showing graphical representations underdamped and critically damped system, according to an exemplary embodiment. With reference to FIG. 27A, there is shown a graphical representation 2700A of an underdamped system and FIG. 27B shows a graphical representation 2700B the system converted to a critically damped. In an embodiment, the load blinker 102 detection, with the ζ and ωₙ known, we can design a filter system that dampens the underdamped inrush current accurate. This filtered signal allows for the linearization and scaling of the signal. Which allows for accurate Load Blinker detection for previously undetectable events.

In an embodiment, the detection of transmission signals can be significantly improved when the damping ratio (ζ) and natural frequency (ωₙ) of the system are known. These parameters serve as the foundation for designing a filter system that can effectively dampen the underdamped inrush current, enhancing the signal's clarity and interpretability. More specifically, knowing the ζ and ωₙ of the system, we can design a filter that can accurately suppress the excessive oscillations characteristic of an underdamped system. This filter works to minimize the effect of these oscillations on the signal, ensuring that the true signal is not masked or distorted by these unwanted fluctuations.

In an embodiment, once the underdamped inrush current is properly mitigated by the filter, the resultant signal becomes more manageable. This filtering process significantly aids in the linearization and scaling of the signal, making it easier to analyze and interpret. Furthermore, the linearized and scaled signal enhances the reliability of the transmission signal detection process. It enables us to distinguish and detect events that were previously hidden or undetectable amidst the noise and oscillations. Consequently, this more refined and precise detection capability aids in more accurate system analysis and control and can even enable proactive maintenance and troubleshooting.

FIG. 28 is an illustration showing effect of natural frequency and damping ratio on behavior of an electrical equipment, according to an exemplary embodiment. With reference to FIG. 28, there is shown 2800 effect the natural frequency (ωₙ) and damping ratio (ζ) are significant factors in understanding the behavior of electrical equipment, HVAC systems, and other load equipment powered through circuit breakers. These parameters provide insights into the system's characteristics, such as stability and response speed, and aid in identifying the nature and configuration of the components within. Consequently, they form an essential part of the analysis, troubleshooting, and maintenance process of these systems.

In an embodiment, the power monitoring system or every piece of electrical equipment has a specific ωₙ and ζ, determined by the electrical and mechanical properties of its components. For example, in an electrical circuit, the on is predominantly influenced by the circuit's inductance and capacitance. High ωₙ might imply the presence of small inductors or capacitors, while a low on could indicate larger inductive or capacitive components. Similarly, the ζ of the system provides insights into its inherent damping mechanisms, hinting at the types and presence of resistive elements in the system.

In the context of HVAC systems, the blower fan's rotational speed might be akin to the ωₙ, and the dampers in the ductwork might contribute to the system's ζ. For other load equipment, these values can vary greatly, depending on their specific electrical design and mechanical characteristics. By understanding the ωₙ and ζ of these systems, it becomes possible to predict their response to changes in input or disturbances, which is crucial in designing and optimizing control strategies. For instance, if the system has a high ζ, it might quickly return to a steady state after a disturbance, indicating robust damping mechanisms. In contrast, a system with a low ζ might exhibit sustained oscillations, indicating requirement for control strategies that increase damping. Overall, a thorough understanding of ωₙ and ζ not only gives insights into the system's current behavior but also provides the ability to predict how the system will respond under different conditions. This knowledge forms the cornerstone for effective troubleshooting, efficient maintenance, and optimized control of these systems.

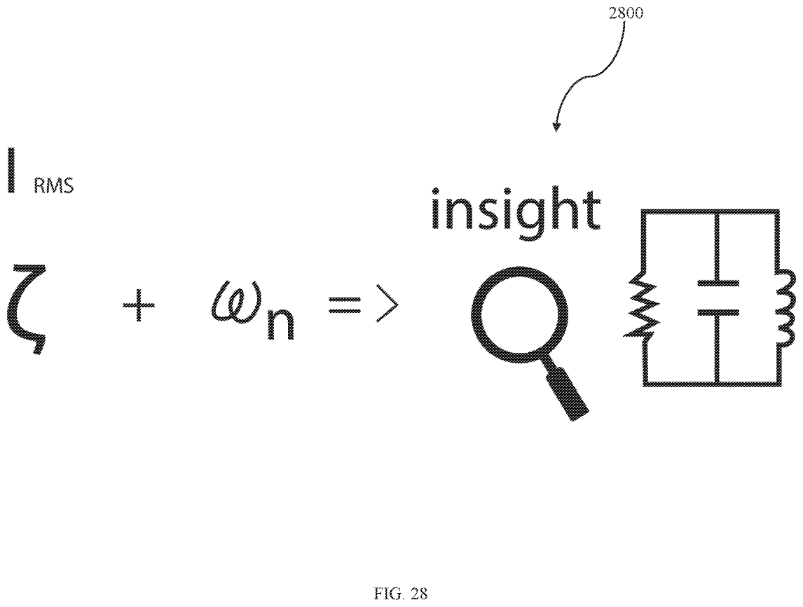

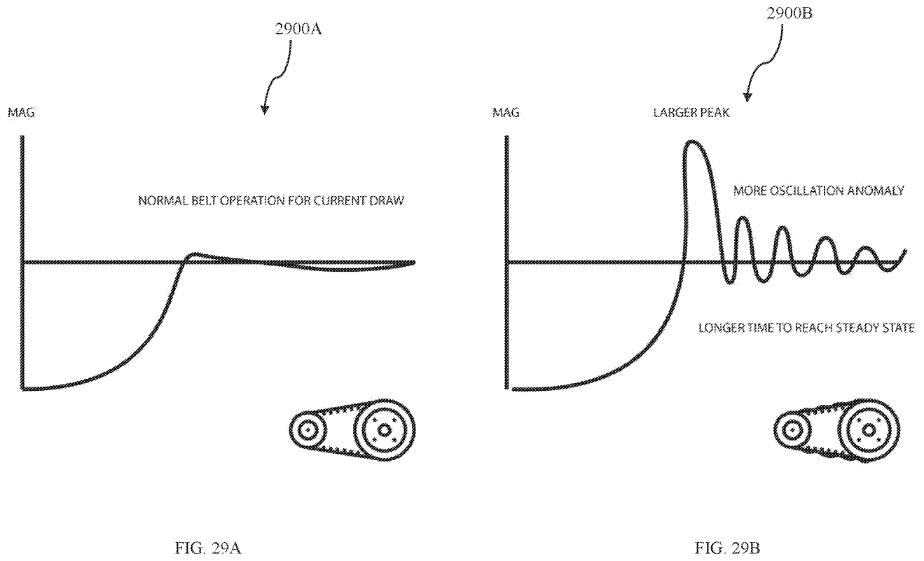

FIG. 29A and FIG. 29B are illustrations showing belt malfunctions, according to exemplary embodiments. With reference to FIG. 29A, there is shown a graphical representation 2900A and FIG. 29B shows graphical representation 2900B. In an embodiment, when a component like a belt malfunctions, it can directly affect the system's step response, possibly leading to increased oscillations and a slower return to steady-state. This behavior typically reflects as a lower damping ratio (ζ), indicating less damping in the system, and possibly a change in the natural frequency (ωₙ). Thus, the system can appear more unstable. By observing these changes, it can provide a clear indication that a malfunction has occurred.

In an embodiment, the step response of a system offers valuable information about its performance and health. When a component like a belt in an HVAC system or a mechanical machine malfunction, it changes the system's dynamics. The belt, which contributes to the system's natural frequency (ωₙ), can alter this frequency if it's worn, stretched, or broken. This could lead to a slower response, reflected by a lower ωₙ. Moreover, the malfunctioning belt can affect the system's damping, reducing its ability to mitigate oscillations after a disturbance. This condition typically results in a lower damping ratio (ζ), leading to more prolonged and possibly increased oscillations in the system's response.

The changes in the system's step response can be noticed and analyzed in real-time or via logged data. This alteration in ωₙ and ζ provides an opportunity to identify and isolate the malfunctioning component based on the changes in the system's dynamic behavior. Thus, understanding and tracking the step response and related parameters of a system form an integral part of preventive maintenance and troubleshooting. It not only assists in detecting malfunctions early but also helps maintain the system's stability and reliability, ensuring its longevity and efficient operation.

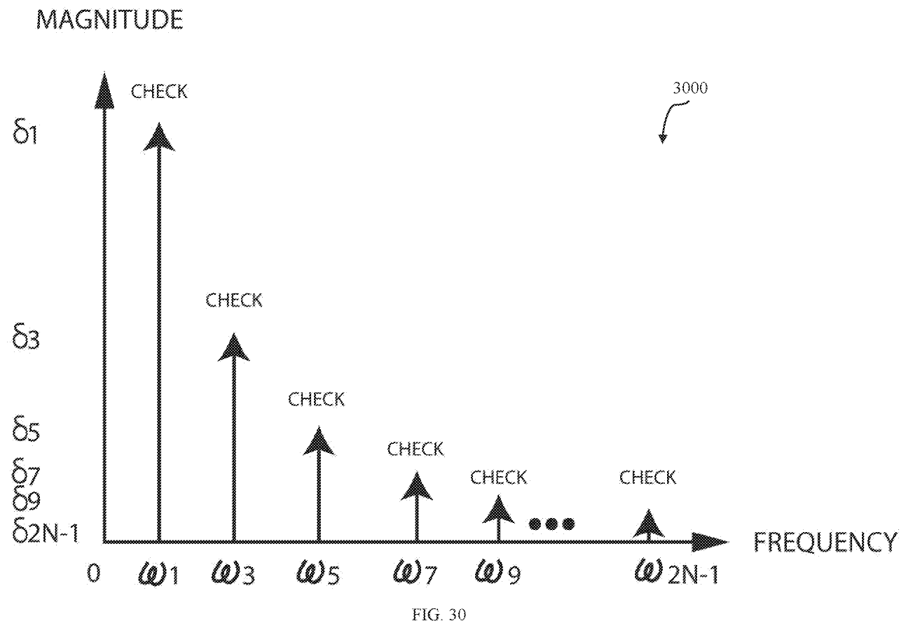

FIG. 30 is an illustration showing high level raw FFT to output of the idealized load blinker, according to an exemplary embodiment. With reference to FIG. 30, there is shown a graphical representation 3000 that illustrates output showing the high level raw FFT to output of the idealized load blinker signal, at each frequency bin of the expected output. Check if it is within a defined threshold of expected values. In an embodiment, the Fast Fourier Transform (FFT) is a computational algorithm used to convert a signal from its time domain to the frequency domain. The FFT output for the “idealized load blinker signal” indicates the presence and strength of various frequency components within the signal. Essentially, it provides a spectrum of frequencies, each associated with a particular amplitude, representing the strength of that frequency within the signal.

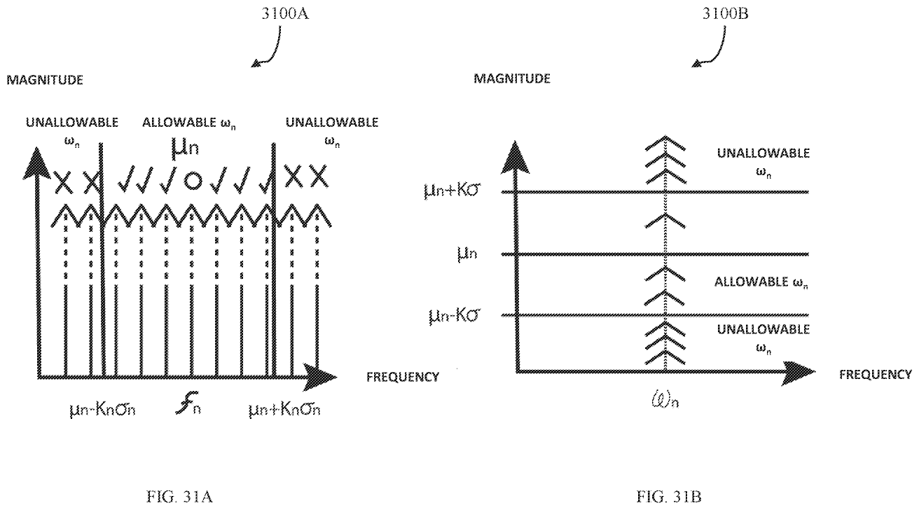

FIG. 31A and FIG. 31B are illustrations showing frequency and amplitude distributions, according to exemplary embodiments. With reference to FIG. 31A, there is shown 3100A and FIG. 31B there is shown 3100B. In an embodiment, the Fast Fourier Transform (FFT) provides outputs ωn and δn at harmonic n, representing the frequency and amplitude distributions respectively. The on shows the frequency distribution and its variance, defined by multiple iterations of standard deviation, while on reflects the amplitude distribution with its own variance defined similarly. These results allow the verification of whether these distributions fall within an acceptable range. It aids in understanding the system's behavior and helps identify any anomalies.

In an embodiment, the FFT is employed to analyze the signal in terms of its frequency and amplitude distributions at each harmonic. The on output of the FFT represents the distribution of frequencies at the nth harmonic. It provides a critical insight into the harmonic content of the signal. The deviation of the frequency distribution from expected values, calculated as an iteration of standard deviation (first, second, third, etc.), is a valuable metric to identify any irregularities or anomalies in the signal's frequency spectrum. Similarly, the on output provides information about the amplitude distribution at the nth harmonic. It gives an understanding of how strongly each harmonic is represented in the signal. Again, the deviation of the amplitude distribution from expected values, defined by an iteration of standard deviation (first, second, third, etc.), can act as an indicator of any abnormalities in the signal's amplitude content. Together, the ωn and δn outputs from the FFT analysis offer a comprehensive view of the signal's frequency and amplitude characteristics. They allow a detailed evaluation of the signal against defined thresholds as exemplarily shown in FIG. 31, aiding in the detection of any deviations and anomalies. This information is essential for monitoring system performance, identifying issues, and implementing corrective actions.

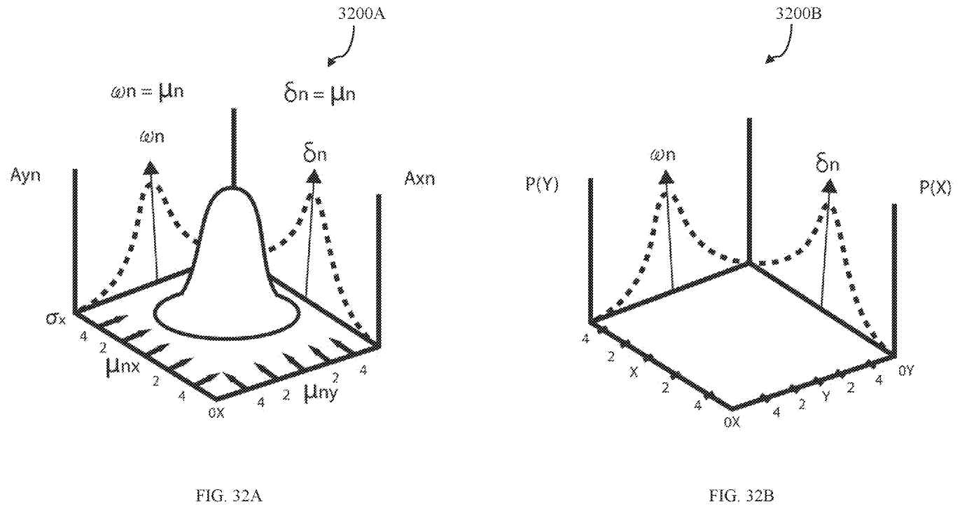

FIG. 32A and FIG. 32B are illustrations showing distribution of amplitude and frequency for FFT output, according to exemplary embodiments. With reference to FIG. 32A, there is shown a graph 3200A and FIG. 32B, there is shown a graph 3200B. These graphs respectively represent the distribution of amplitude and frequency for the Fast Fourier Transform (FFT) output as a multivariate Gaussian curve. This multivariate analysis combines the probability density functions of both the amplitude and frequency. The resulting 3D Gaussian curve provides a visual representation of the system's behavior in terms of both variables. It helps to analyze the signal's characteristics, revealing the correlation and interaction between frequency and amplitude.

The FFT is a computational tool that provides insight into the frequency and amplitude distribution of a signal. The graph under discussion represents these two dimensions-amplitude and frequency-within the same framework as a multivariate Gaussian curve. This curve is a statistical distribution that allows us to visualize and understand the interaction between multiple random variables, in this case, the amplitude and frequency.

The uniqueness of this graph compared to traditional ones is its ability to present both dimensions (amplitude and frequency) in a single, three-dimensional Gaussian curve. The x and y-axes represent the amplitude and frequency, respectively, while the z-axis corresponds to the probability density. Each point in this 3D space shows the combined probability density of a particular amplitude-frequency pair, which can provide more comprehensive information about the signal's characteristics. Such a multivariate Gaussian curve effectively illustrates the concurrent behaviors of amplitude and frequency, revealing the correlation between them. It can highlight any peculiarities in their interaction, which could be indicative of system anomalies such as noise on the line or specific operational states. This makes it an invaluable tool for signal analysis, enabling more accurate system monitoring and troubleshooting.

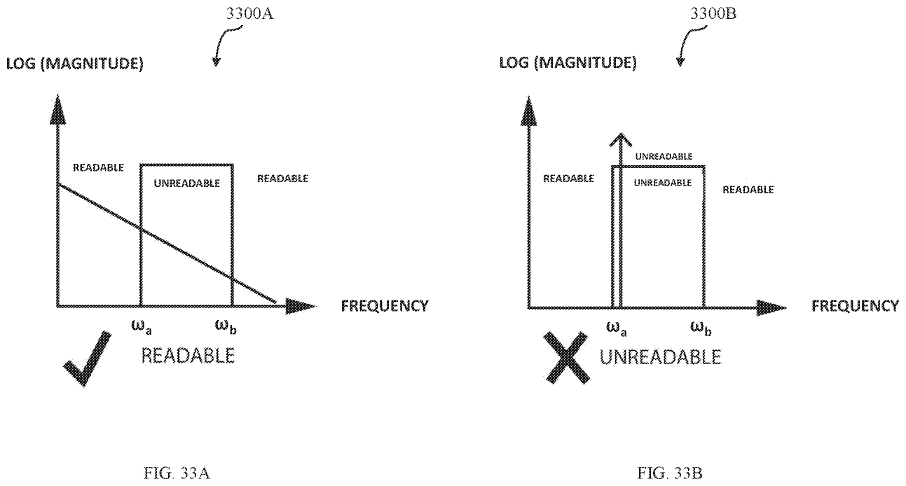

FIG. 33A and FIG. 33B show illustrations of logarithmically scaled frequency output, according to exemplary embodiments. With reference to FIG. 33A, there is shown a graph 3300A and with reference to FIG. 33B, there is shown a graph 3300B. In an embodiment, the graphs 3300A and 3300B may represent a logarithmically scaled frequency output from a system with a load blinker signal and random signal noise within the frequency range ωa to ωb is shown. This noise can be mitigated by the load blinker's square wave harmonic signal. Notably, even if the signal appears anywhere along the frequency axis, Load Blinker's trending data remains recoverable. However, if the load blinker produces a limited harmonic series or a single sine wave, the risk of noise signal overlap increases significantly. This overlap can complicate the process of signal recovery and interpretation.

In this system, the output frequency is represented on a logarithmic scale, which helps to clearly visualize frequency components that vary across several orders of magnitude. The system incorporates a load blinker, which produces a characteristic signal amidst other random noise signals occurring between the frequency ranges ωa to ωb. The load blinker's signal is likened to a square wave, rich in harmonics, which can effectively counteract the noise present in the system. This harmonic richness helps to differentiate the load blinker signal from random noise, even when the noise falls within the same frequency spectrum. It's important to note that even if the load blinker's signal is observed at any point along the frequency axis, the trending data—that is, the characteristic changes and patterns over time-remain recoverable. This recovery is possible due to the distinct harmonic content of the Load Blinker's signal, which sets it apart from the random noise. However, if the load blinker were to generate a limited harmonic series or merely a single sine wave, the chances of encountering an overlapping noise signal would rise dramatically. Such overlap could confuse the distinction between signal and noise, potentially leading to incorrect interpretations and decreased system performance.

### INDUSTRIAL APPLICABILITY

In one mode of operation, the user would install the current monitoring device in which CTs would be connected to every circuit breaker on the panel. The user would walk around the building with another device i.e., the second device containing the transmitter that would transmit the unique signal to help identify the different types of wall fixtures e.g., electrical sockets, light switches and other electrical appliances associated with each of the respective circuit breakers. The CTs would compute on-board to identify when and where the corresponding load blinker was to triangulate it with the correct wall socket and or light switch or any electrical output junction. After this calculation is finished while the user is walking around. When the user returns to the circuit breaker panel the user would forward the information from the current monitoring device to the app via wireless communication such as Bluetooth, WiFi, LoRa etc.

In another mode of operation, the user would install the current monitoring device that would connect to every circuit breaker on the panel. The user would walk around the building with a device that would transmit the unique signal that would identify the wall plugs and light switches and other electrical outputs to the correct circuit breaker. The CT would compute on board most of the information and to identify the most key useful information to then transmit this to a cloud for the AI to identify whether the signal was on the line. This is to identify when and where the load blinker was to triangulate it with the correct wall socket and or light switch or any electrical output junction. After this calculation is finished while the user is walking around. When the user returns to the circuit breaker panel the user would forward the information from the current monitoring device to the app via wireless communication such as Bluetooth, WiFi, LoRa etc.

One option is that a user could use the load blinker with our receiver, or a aftermarket power monitoring system to be installed or with a smart panel that comes with power monitoring factory ready on each breaker. Another option is to use one Load Blinker+Phone pair or more than one Load Blinker Pair to speed up the mapping process with multiple people mapping the sight simultaneously.

Additionally, this system could only do this service and or it could do the complete labelling and circuit directory creation that are regular power monitoring system does. For example, this would include power monitoring and power management of the sites documentation and as-is building conditions for service workers to use to keep the system smart and always up to date.

After the calibration is complete the power monitoring receiver could be removed for only the identification and labelling service or it could be left in to continue to monitor the system. Since the power monitoring system now has the entire digitized system including the load information the trending of the power with the specific equipment information becomes more valuable as if the circuit is dedicated the equipment information power usage characteristics can be used for anomalies and predictive maintenance activities such as replacing a broken belt, change dirty filters, bad water heater elements, leaks, irregular system running conditions such as lights left “ON” or parking lot lights “ON” during the day or if there are other lighting and/or heating schedule irregularities.

The power monitoring system may be left in permanently installed in electrical circuits for monitoring power. As stated earlier, the power monitoring system may operate or function as a digital twin of the electrical circuits it is installed on. Moreover, the power monitoring system can not only measure multiple loads on a single line while accounting and reporting any previously undetected loads on the line, but also loads that form part of a different, but interconnected, electrical circuit which can potentially happen, for instance, when a neutral from one circuit breaker is common with another circuit breaker, or in another instance, a common neutral is used on two power lines routed via a common circuit breaker or two or more distinct circuit breakers. Also, the power monitoring system may blink loads e.g., switches and breakers of lamps, or other fixtures using its smart adapters as part of its central, or consolidated, testing procedure to match the demand of electrical power by the electrical loads on a corresponding power supply line

In an embodiment, the power monitoring system may implement use of multiple power monitoring systems to monitor “power loss events” that are triggered by the user of the system by following the prompts of a mobile app to cycle breakers at one or more panels to create triggered power loss events. Timestamps of the triggered power loss events at the panel's circuit breakers and the load terminals can be recorded. The triggered power loss events at each of the panel's circuit breakers are matched to the power loss events at the corresponding load, or the respective load's terminal using these recorded timestamps to map individual circuit breakers to their corresponding loads as power loss may be detected almost instantaneously (within microseconds, milliseconds or seconds) of the directed triggered event at the circuit breaker. Moreover, the power monitoring systems described in the subject specification is capable of collecting and storing these records digitally.

Modifications to embodiments of the present disclosure described in the foregoing are possible without departing from the scope of the present disclosure as defined by the accompanying claims. Expressions such as “including”, “comprising”, “incorporating”, “consisting of”, “have”, “is” used to describe and claim the present disclosure are intended to be construed in a non-exclusive manner, namely allowing for items, components or elements not explicitly described also to be present. Reference to the singular is also to be construed to relate to the plural.

What is claimed is:

1. A system for tracing and monitoring power lines of electrical networks, the system comprising:
a first device configured with at least one transmitter and connected to a power line, wherein the first device transmits at least one signal associated with an amplitude, a phase, a frequency, a switching frequency and a duty cycle of current including a plurality of current signatures, wherein the plurality of current signatures include a unique first current signature associated with the first device and at least one second current signature associated with one or more load fixtures connected on the power line,
wherein the at least one signal is transmitting by one or more of a plurality of metal-oxide-semiconductor field-effect transistors (MOSFETs), a plurality of bipolar junction transistors (BJTs), a plurality of insulated-gate bipolar transistors (IGBTs), a plurality of relays, a plurality of triacs to modulate a load and current of the power line;
a second device configured with at least a receiver and connected to a circuit breaker switch disposed upstream of the first device and located on an electrical panel, wherein the second device is in communication with the transmitter of the first device to receive the at least one signal transmitted therefrom;
a power monitoring system in communication with the receiver of the second device, the power monitoring system comprising a processor configured to:
process the at least one signal received at the second device using Fast Fourier Transform (FFT) including the plurality of current signatures for obtaining the unique first current signature of the first device and at least one second current signature associated with the one or more load fixtures;
send at least one signal from the receiver to the transmitter to confirm whether the power line on which the one or more load fixtures are connected is the power line that is connected to the circuit breaker;
determine whether total current input to the power line via the circuit breaker matches with a sum of currents to the first device and the one or more load fixtures as indicated from data contained in the at least one signal communicated by the transmitter to the receiver; and
generate a user intelligible data representation of the confirmation and determination.

2. The system of claim 1, wherein the first device and the second device comprise one of:
at least one current transformer (CT) and at least one impedance load respectively; or
at least one CT and at least one potential transformer (PT) respectively; or
at least one CT and at least one CT respectively.

3. The system of claim 2, wherein the at least one potential transformer of the transmitter includes a load blinker.

4. The system of claim 3, wherein the processor of the power monitoring system is configured to implement one or more machine learning (ML) algorithms to trace the power line via detection of the load blinker.

5. The system of claim 4, wherein, on the current flowing through the power line, the processor of the power monitoring system is configured to perform at least one of: an amplitude modulation, a load impedance modulation, a phase modulation, a frequency modulation, a switching frequency modulation and a duty cycle modulation.

6. The system of claim 5, wherein the ML model used by the processor includes at least one of a black box model, a grey box model or a white box model.

7. The system of claim 1, wherein when the processor determines, from data contained in the at least one signal communicated by the transmitter to the receiver, that the total current input to the power line via the circuit breaker does not match with the sum of currents to the transmitter and the one or more serially or parallelly connected load fixtures located downstream of the transmitter, then the processor is configured to flag an undetected load event.

8. The system of claim 1 further comprising: a display and an alert device, each in communication with the processor of the power monitoring unit, wherein the display is configured to virtually represent to the user intelligible data pertaining to the confirmation and determination, and wherein the alert device is configured to provide at least one type of aural feedback indicative of at least one of power line traced to circuit breaker, or presence of at least one undetected load downstream.

9. The system of claim 1, wherein the receiver and the transmitter are configured to communicate with each other using a power line communication (PLC).

10. The system of claim 1 further comprising a memory unit communicably coupled to the processor, the memory unit configured to store thereon:
modulations performed by the processor,
confirmations performed by the processor, and
determinations performed by the processor.

11. The system of claim 1, wherein the power monitoring system, further comprises:
an Internet of Things (IoT) module communicably coupled to the processor; and
at least one client remotely located from the processor and in wireless communication with the IoT module, wherein the client is configured to receive the user intelligible data representations from the processor via the IoT module.

12. The system of claim 1, wherein the least one remotely located client includes: a remote server, cloud, a computer, a laptop, a tablet, a Phablet, or another type of telecommunications device.

13. The system of claim 1, wherein the processor is further configured to generate a plurality of timestamps, wherein the plurality of timestamps enable the processor to:
differentiate and order the plurality of signals based on a time of sending and receiving the plurality of signals;
synchronize an operation between the one or more load fixtures that are connected om the power line; or
record an exact time associated with an image or scan capture during a load mapping process.

14. A method for tracing and monitoring power lines of electrical networks, the method comprising:
connecting a first device configured with at least a transmitter to a power line, wherein the first device transmits at least one signal is associated with an amplitude, a phase, a frequency, a switching frequency and a duty cycle of current including a plurality of current signatures, wherein the plurality of current signatures include a unique first current signature associated with the first device and at least one second current signature associated with one or more load fixtures connected on the power line,
wherein the at least one signal is transmitting by one or more of a plurality of metal-oxide-semiconductor field-effect transistors (MOSFETs), a plurality of bipolar junction transistors (BJTs), a plurality of insulated-gate bipolar transistors (IGBTs), a plurality of relays, a plurality of triacs to modulate a load and current of the power line;
connecting a second device configured with at least a receiver and connected to a circuit breaker switch disposed upstream of the first device and located on an electrical panel, wherein the second device is in communication with the transmitter of the first device to receive the at least one signal transmitted therefrom;
providing a power monitoring system, comprising a processor, in communication with the receiver,
processing, by the processor, the at least one signal received at the receiver using Fast Fourier Transform (FFT) including the plurality of current signatures for obtaining the combined unique current signature for obtaining a first unique current signature of the transmitter and the at least one second current signature associated with the one or more load fixtures;
sending, by the processor, at least one signal from the receiver to the transmitter to confirm whether the power line on which the one or more load fixtures are connected is the power line that is connected to the circuit breaker;
determining, by the processor, whether total current input to the power line via the circuit breaker matches with a sum of currents to the first device and the one or more load fixtures as indicated from data contained in the at least one signal communicated by the transmitter to the receiver; and
generating, by the processor, user intelligible data representation of the confirmation and determination.

15. The method of claim 14 further comprising providing the receiver and the transmitter with at least one of:
at least one current transformer (CT) and at least one impedance load respectively; or
at least one CT and at least one potential transformer (PT) respectively; or
at least one CT and at least one CT respectively.

16. The method of claim 16, wherein providing the at least one potential transformer (PT) to the transmitter includes providing the transmitter with a load blinker.

17. The method of claim 14, wherein the processor of the power monitoring system is configured to implement one or more machine learning (ML) algorithms to trace the power line via detection of the load blinker.

18. The method of claim 13 further comprising: flagging an undetected load event, wherein the undetected load event is flagged when the processor determines that the total current input to the power line via the circuit breaker does not match with the sum of currents to the transmitter and the one or more serially or parallelly connected load fixtures located downstream of the transmitter.

19. The method of claim 14 further comprising: providing: a display and an alert device, each in communication with the processor of the power monitoring unit, wherein the display is configured to virtually represent to the user intelligible data pertaining to the confirmation and determination, and wherein the alert device is configured to provide at least one type of aural feedback indicative of at least one of power line traced to circuit breaker, or presence of at least one undetected load downstream.

20. The method of claim 14 further comprising providing a memory unit in communication with the processor, the memory unit configured to store thereon:
modulations performed by the processor,
confirmations performed by the processor, and
determinations performed by the processor.

21. The method of claim 14, wherein the power monitoring unit, further comprises providing:
an Internet of Things (IoT) module communicably coupled to the processor; and
at least one remotely located client disposed in wireless communication with the IoT module such that the client is configured to receive user intelligible data representations from the processor via the IoT module.
